(19) United States
(12) Patent Application Publication
(10) Pub. No.: US 2005/0027491 A1
(43) Pub. Date: Feb. 3, 2005

(54) Symbolic analysis of electrical circuits for application in telecommunications

(75) Inventors: Antoni Fertner, Solna (SE); Edwin Luppert, Sodertalje (SE)

Correspondence Address: NIXON & VANDERHYE, PC, 1100 N GLEBE ROAD, 8TH FLOOR, ARLINGTON, VA, 22201-4714, US

(73) Assignee: Telefonaktiebolaget LM Ericsson (publ), Stockholm (SE)

(21) Appl. No.: 10/628,578

(22) Filed: Jul. 29, 2003

(51) Int. Cl. H03F 1/26

(52) U.S. Cl. 702/196

(57) ABSTRACT

Analysis of an electrical circuit is performed using a computer program product (60) and a method. In accordance with the program and the method, a electrical circuit analyzer generates an admittance matrix for an electrical circuit which is being analyzed. The admittance matrix includes symbolic expressions rather than numerical expressions for at least some components of the electrical circuit. The electrical circuit analyzer linearly and algebraically solves an equation system including the admittance matrix for analyzing at least a part of the electrical circuit. The electrical circuit analyzer uses symbolic computation to solve the equation system including the admittance matrix for analyzing at least a part of the electrical circuit. The equation system including the admittance matrix can be solved in various types of analyses, including (1) determining a transfer function between specified nodes of the electrical circuit; and (2) optimizing a component of the electrical circuit. The electrical circuit analyzer sets up the admittance matrix Y by following a set of “rules”. Special rules are provided for certain telecommunications components, such as multi-winded transformers, loading coils, line-drivers, analogue cables, and filters. Inclusion of these special rules for telecommunications components enables the electrical circuit analyzer to be more applicable to telecommunications circuits than conventional analyzers. In accordance with a block/subcircuit matrix approach, an overall circuit is divided into plural subcircuits. In such case, the admittance matrix can comprise separate admittance blocks for each of plural subcircuits. Connectivity blocks which represent connectivity between the plural subcircuits are situated on a cross diagonal of the admittance matrix. The admittance matrix can then be conveniently utilized for analyzing at least a part of the electrical circuit. Advantages of this approach include recursively reducing the size of the matrices including the admittance matrix as subcircuits are added to the admittance matrix.

### BACKGROUND

1. Field of the Invention

This invention relates to method and apparatus for the analysis of electrical circuits, and particularly to the analysis of circuits utilized in a telecommunications system.

2. Related Art and Other Considerations

In various fields of technical endeavor it is often important to determine a transfer function between two arbitrary points of an electrical circuit or to analyze an electrical circuit for purposes such as, for example, optimizing component values. To this end various software products purport to model and analyze analogue electronic circuits.

Some of these circuit analysis products make use of a general method, known as modified nodal analysis, for constructing and solving the circuit equations. Raymond A. DeCarlo and Pen-Min Lin, “Linear Circuit Analysis”, Oxford University Press, 2001, ISBN 0-19-51366-7. Nodal Analysis is based on Kirchoff's Current Law (KCL), i.e., the sum of all currents entering and leaving a node is zero. Each entering/leaving current depends on the branch conductance. A set of nodal equations is obtained by applying KCL to each node. Solving these equations yields the potentials of all branches in the circuit. A number of elements, such as dependent voltage/current sources require auxiliary equations for determining their unknown voltages or currents. KCL applies not only for nodes, but also for the closed curves or surfaces, as Gaussian curves, Gaussian surfaces or supernodes. For lumped circuits, this implies that the sum of the currents leaving a supernode (which has a distinctly separated inside and outside) is zero.

Among the software products which model and analyze analogue electronic circuits is Analog Insydes, a Mathematica toolbox, which has been employed for custom design of analog integrated circuits. Analog Insydes lends itself to analysis of non-linear devices, symbolic approximation strategies, and especially to approximations of non-linear differential equations.

Analyzing electrical circuits in the telecommunications industry has special considerations and requirements which are not fully satisfied by existing analysis products. But whereas some existing analysis products are particularly applicable for non-linear devices, in telecommunications circuits the non-linearity of certain devices (such as line drivers, for example) is generally quite small and of negligible influence on the overall telecommunications system. In telecommunications systems, other factors such as the value spread of components incorporated in the circuitry of the system is of significantly greater importance and can cause severe problems (e.g., for high-speed data transceivers).

Moreover, existing circuit analysis products such as Analog Insydes do not provide support for some devices which are often employed in telecommunications environments, such as cables/communication channels, non-ideal transformers with several windings, digital filters, etc. For example, transformers with more than two windings are very difficult to model and analyze. Yet transformers with three, four, or even more windings are commonly utilized in telecommunications applications. Thus, non-support for such telecommunications devices drastically curtails employment of the existing circuit analysis products in the telecommunications environment.

Some circuit analysis products function essentially as simulators and analyze signals in the time domain. Included among such simulators are products known as PSpice, TINA, Saber, Cossap, and Eldo. These simulators lack full suitability for analysis of telecommunication circuits.

### BRIEF SUMMARY

Analysis of an electrical circuit is performed using a computer program product and a method. In accordance with the program and the method, an electrical circuit analyzer generates an admittance matrix for an electrical circuit which is being analyzed. The admittance matrix is part of an equation system YV=I, where I is a current vector, Y is the admittance matrix, and V is the potential (voltage) vector.

Whereas conventional admittance matrices includes numerical expressions for components of the electrical system, in accordance with the program and method herein described the admittance matrix includes symbolic expressions rather than numerical expressions for at least some components of the electrical circuit, and in some cases for all components of the electrical circuit. The electrical circuit analyzer linearly and algebraically solves an equation system including the admittance matrix for analyzing at least a part of the electrical circuit. That is, the electrical circuit analyzer uses symbolic computation to solve the equation system.

By using the symbolic processing of the electrical circuit analyzer, a signal is represented as a formula, instead of a stream of numbers. The required function is expressed in terms of symbols until it becomes convenient to compute it numerically. Thus, the electrical circuit analyzer uses symbolic matrix formulations of electrical circuits and formal techniques to solve equations resulting in closed-form symbolic expressions. There is no need to use sophisticated techniques for integrating differential equations.

The equation system including the admittance matrix can be applied or utilized in various types of analyses, including (1) determining a transfer function between specified nodes of the electrical circuit; (2) optimizing a component of the electrical circuit, (3) perturbation/sensitivity analysis, and (4) general circuit design.

The electrical circuit analyzer sets up the admittance matrix Y by following a set of “rules”. There is a different rule for each different type of component included in the electrical circuit. The column and row positions of the admittance matrix Y affected by the inclusion of the circuit element are typically related to the particular nodes of the circuit to which the circuit component is connected. Special rules are provided for certain telecommunications components, such as multi-winded transformers, loading coils, line-drivers, analogue cables, and filters. Inclusion of these special rules for telecommunications components enables the electrical circuit analyzer to be more applicable to telecommunications circuits than conventional analyzers.

In general, matrix equations can become increasingly time-consuming and especially memory-consuming when dealing with very large circuits containing many components. Additionally, some components require extensive use of auxiliary equations, which may also contribute to memory deficiencies. In order to minimize these factors, as one of its aspects the electrical circuit analyzer implements a block matrix approach rooted in Krakovian algebra, which is related to matrix algebra. Then, using standard programs (such as, for instance, those implemented in Matlab), the Krakovian algorithm can be easily executed.

In accordance with the block/subcircuit approach, an overall circuit can be divided into plural subcircuits, for example a subcircuit and a main circuit, the main circuit being exterior to the subcircuit. In such case, the admittance matrix can comprise separate admittance blocks for each of plural subcircuits, e.g., a separate subcircuit admittance block for the subcircuit and a main circuit admittance block for the main circuit. The admittance blocks for the plural subcircuits are situated on a main diagonal of the admittance matrix. Moreover, connectivity blocks which represent connectivity between the plural subcircuits are situated symmetrically across the main diagonal. The admittance matrix can then be conveniently utilized for analyzing at least a part of the electrical circuit.

In one mode, the generation of the subcircuit admittance block for the subcircuit comprises generating a subblock for the subcircuit; generating an internal voltage subblock for the subcircuit; and, generating a surface connectivity sub block for the subcircuit. The subblock for the subcircuit can be one of an impedance subblock, a chain matrix, a scattering matrix, etc.

In one mode, generation of the connectivity blocks comprises generating a current exchange connectivity block which describes how currents are exchanged between the main circuit and the subcircuit; generating a voltage potential connectivity block which describes voltages at common nodes between the main circuit and the subcircuit; and, inserting the current exchange connectivity block and the voltage potential connectivity block in the admittance matrix.

The subcircuit can be of any configuration and can comprise a telecommunication component such as a multi-winded transformer, a loading coil, a line-driver, an analogue cable, and a filter.

According to an advantage this block/subcircuit approach, the size of the entire admittance matrix comprising block Krakovians corresponding to the subcircuits can be recursively reduced, working only with those matrix blocks that are relevant for a specific application. Moreover, the resulting admittance matrix Y dynamically changes its dimensions depending on the number of equations required to describe a subcircuit. Therefore, the solution matrix has approximately the same dimension as the number of relevant equations.

Expressing a large circuit in terms subcircuits makes the circuit description easier to interpret. The subcircuit concept can be used many times without creating an excessive amount of equations. The subcircuit concept can also save the number of arithmetical operations.

### BRIEF DESCRIPTION OF THE DRAWINGS

The foregoing and other objects, features, and advantages of the invention will be apparent from the following more particular description of preferred embodiments as illustrated in the accompanying drawings in which reference characters refer to the same parts throughout the various views. The drawings are not necessarily to scale, emphasis instead being placed upon illustrating the principles of the invention.

FIG. 1 is a schematic view of an example circuit analysis workstation according to an embodiment of the invention.

FIG. 2 is a schematic view of an organization of programs executable by circuit analysis workstation, the programs including an electrical circuit analyzer.

FIG. 2A is a schematic view of an organization of programs executable by circuit analysis workstation, the programs including (1) a MATLAB program which runs an electrical circuit analyzer from a script and (2) a particular schematic editor program.

FIG. 3A is a schematic view of an equation system including an admittance matrix.

FIG. 3B is a schematic view of an equation system including an admittance matrix structured in consideration of a subcircuit, and thus a rule for placing a subcircuit in an admittance matrix.

FIG. 3C is a schematic view of an equation system including an admittance matrix structured to accommodate plural subcircuits.

FIG. 4A(1)(a) is a schematic view of a resistor; FIG. 4A(1)(b) is a schematic view of an open end; FIG. 4A(2) is a schematic view illustrating a rule for placing a resistor or an open end in an admittance matrix.

FIG. 4B(1) is a schematic view of a capacitor; FIG. 4B(2) is a schematic view illustrating a rule for placing a capacitor in an admittance matrix.

FIG. 4C(1) is a schematic view of an inductor; FIG. 4C(2) is a schematic view illustrating a rule for placing an inductor in an admittance matrix.

FIG. 4D(1) is a schematic view of a gain; FIG. 4D(2) is a schematic view illustrating a rule for placing a gain in an admittance matrix.

FIG. 4E(1) is a schematic view of an adder; FIG. 4E(2) is a schematic view illustrating a rule for placing an adder in an admittance matrix.

FIG. 4F(1) is a schematic view of an operational amplifier; FIG. 4F(2) is a schematic view illustrating a rule for placing an operational amplifier in an admittance matrix.

FIG. 4G(1) is a schematic view of a CCCSource; FIG. 4G(2) is a schematic view illustrating a rule for placing a CCCSource in an admittance matrix.

FIG. 4H(1) is a schematic view of a CCVSource; FIG. 4H(2) is a schematic view illustrating a rule for placing a CCVSource in an admittance matrix.

FIG. 4I(1) is a schematic view of a VCCSource; FIG. 4I(2) is a schematic view illustrating a rule for placing a VCCSource in an admittance matrix.

FIG. 4J(1) is a schematic view of a VCVSource; FIG. 4J(2) is a schematic view illustrating a rule for placing a VCVSource in an admittance matrix.

FIG. 4K(1) is a schematic view of a power supply; FIG. 4K(2) is a schematic view illustrating a rule for placing a power supply in an admittance matrix.

FIG. 4L(1) is a schematic view of a voltage source; FIG. 4L(2) is a schematic view illustrating a rule for placing a voltage source in an admittance matrix.

FIG. 4M(1) is a schematic view of a cable; FIG. 4M(2) is a schematic view illustrating a rule for placing a cable in an admittance matrix.

FIG. 4N(1) is a schematic view of an ideal transformer; FIG. 4N(2) is a schematic view illustrating a rule for placing an ideal transformer in an admittance matrix.

FIG. 4O(1) is a schematic view of coupled inductors.

FIG. 4P(1) is a schematic view of a transfer function; FIG. 4P(2) is a schematic view illustrating a rule for placing a transfer function in an admittance matrix.

FIG. 4Q(1) is a schematic view of an example subcircuit for illustrative purposes.

FIG. 5 is a schematic view of a first example electrical circuit which undergoes analysis (for determination of a transfer function) by the electrical circuit analyzer of FIG. 2.

FIG. 6 is a diagrammatic view of a matrix equation for the example electrical circuit of FIG. 5.

FIG. 7 is a flowchart showing basic, representative steps involved in a main circuit analysis program.

FIG. 8 is a diagrammatic view of an example screen display generated by the electrical circuit analyzer of FIG. 2 for the example electrical circuit of FIG. 5, and specifically showing the transfer function between nodes N1 and N5 thereof.

FIG. 9 is a flowchart showing basic, representative steps involved a technique for inverting partitioning matrices implemented by the electrical circuit analyzer of FIG. 2.

FIG. 10 is schematic view showing rearranging of a matrix in accordance a technique for inverting partitioning matrices implemented by the electrical circuit analyzer of FIG. 2.

FIG. 11 is a flowchart showing basic steps involved in generation of an Admittance matrix according to a block/subcircuit matrix approach implemented by the electrical circuit analyzer of FIG. 2.

FIG. 11A is a flowchart showing basic steps involved in generation of an admittance block for a subcircuit according to a block/subcircuit matrix approach implemented by the electrical circuit analyzer of FIG. 2.

FIG. 12 is a schematic view of a second example electrical circuit which undergoes analysis by the electrical circuit analyzer of FIG. 2.

FIG. 13 is a diagrammatic view of an admittance matrix for the circuit of FIG. 12.

FIG. 14 is a diagrammatic view of an equation system generated by electrical circuit analyzer of FIG. 2 for the example electrical circuit of FIG. 12 using the admittance matrix of FIG. 13.

### DETAILED DESCRIPTION

In the following description, for purposes of explanation and not limitation, specific details are set forth such as particular architectures, interfaces, techniques, etc. in order to provide a thorough understanding of the present invention. However, it will be apparent to those skilled in the art that the present invention may be practiced in other embodiments that depart from these specific details. In other instances, detailed descriptions of well-known devices, circuits, and methods are omitted so as not to obscure the description of the present invention with unnecessary detail. Moreover, individual function blocks are shown in some of the figures.

1.0 Circuit Analysis Workstation

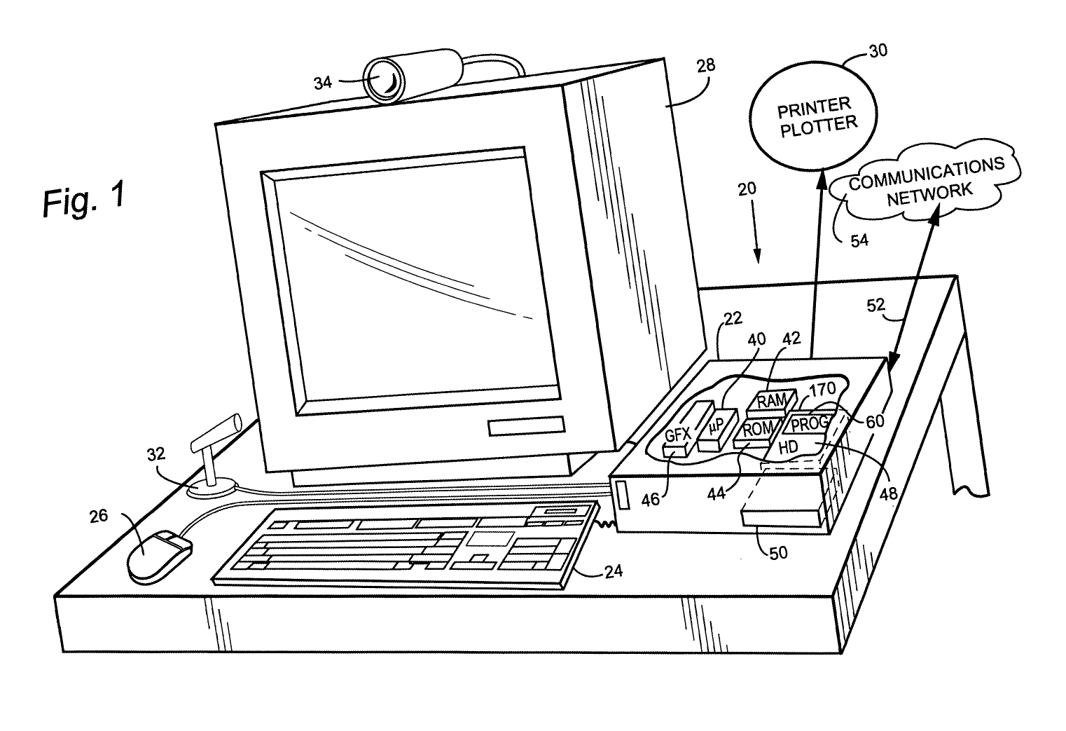

FIG. 1 shows an example embodiment of an circuit analysis workstation 20 which includes a general purpose computer 22 and various input/output devices such as keyboard 24, mouse pointing device 26, display 28, printer/plotter 30, microphone 32, and camera 34. Computer 22 may be, for example, a conventional microcomputer such as an IBM compatible personal computer. As such, computer 22 may include a microprocessor 40, random access memory (RAM) 42, read only memory (ROM) 44, graphics video adapter 46, mass storage device 48 such as a magnetic disk hard drive (HD), and one or more drives 50 for storage media such as an optical disk, a floppy diskette, a video disk (DVD), or a compact disk (CD).

The circuit analysis workstation 20 performs analyses of electrical circuits by execution and under control of an electrical circuit analyzer computer program (PROG) product 60. The electrical circuit analyzer computer program product 60 is also referred to herein more briefly as the electrical circuit analyzer or, in some instances, “Formulae”. The electrical circuit analyzer computer program product 60 may be stored on mass storage device 48 and/or another storage media (e.g., an optical or magnetic disk or compact disk, not shown) provided via one of the drives 50, and loaded into executable memory for execution by microprocessor 40.

A communications connection 52 between computer 22 and a network 54 (e.g., the Internet) may be provided to allow the user to access information from the network and/or exchange information with another computer also connected to the network. It should be understood that the illustration provided in FIG. 1 is only illustrative, and does not show numerous other components, buses, boards, etc., which may constitute general purpose computer 22 and connections to its input/output devices. Moreover, the internal configuration of circuit analysis workstation 20, and the particular input/output devices illustrated in FIG. 1, are merely exemplary and in no way constrain or limit the present invention.

2.0 Electrical Circuit Analyzer: Overview

The electrical circuit analyzer 60 performs symbolic analysis and/or computation for an electrical circuit. The analysis and/or computation may be, for example, to determine a transfer function for or within the circuit. In symbolic processing, a signal is represented as a formula, instead of a stream of numbers. The required function is expressed in terms of symbols and manipulated until it becomes convenient to compute it numerically.

In addition to determining transfer functions, the electrical circuit analyzer 60 can be utilized to optimize a particular component(s) when working in conjunction with other programs or tools. As such, the electrical circuit analyzer 60 can assist the circuit designer to formally express an optimization problem. The inherent complexity of most telecommunication circuits makes this goal very demanding and time-consuming. The electrical circuit analyzer 60 facilitates analysis of very large and complex circuits symbolically, which are otherwise an almost impossible task.

The electrical circuit analyzer computer program product 60 performs the symbolic analysis under the general assumption that the circuit being analyzed is linear and time-invariant. Symbolic analysis gives an insight in the circuit properties, in the behavior and interrelations between various circuit parameters and/or for analyzing transfer-functions. The calculation of the transfer-function(s) is fully automated by electrical circuit analyzer computer program product 60 and several input-output pairs can be defined simultaneously. The transfer function is determined as an expression in terms of circuit elements, frequency, z-variable and constants such as gain, filter coefficients, etc. Hence, the electrical circuit analyzer 60 can be used to evaluate, validate existing circuits or/and to generate functions, which can be used for analyzing the actually developed circuits. In fact, electrical circuit analyzer 60 generates a symbolic expression that would otherwise require an entire program for specific application.

2.1 Electrical Circuit Analyzer: Architecture

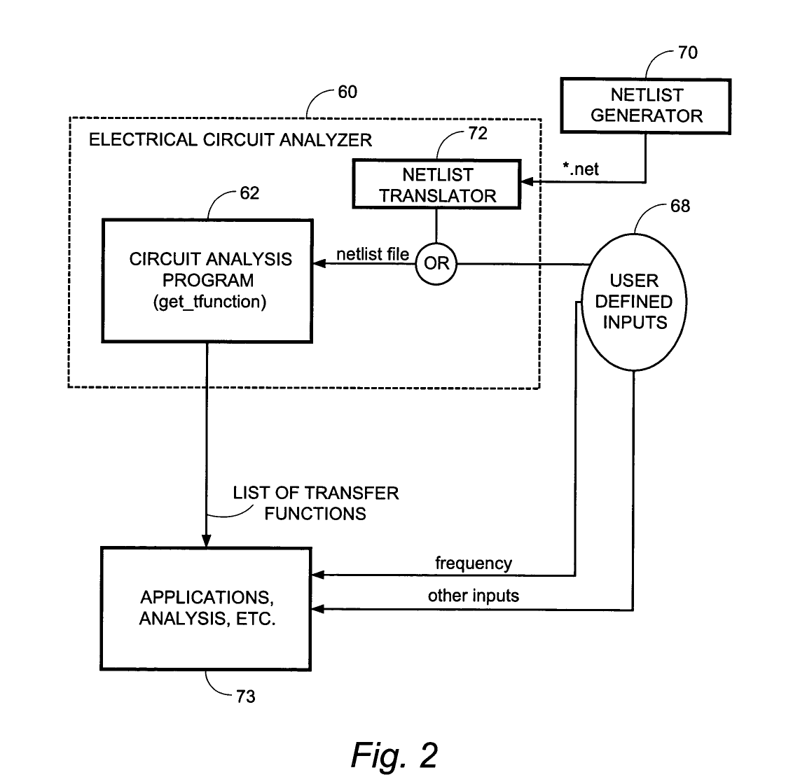

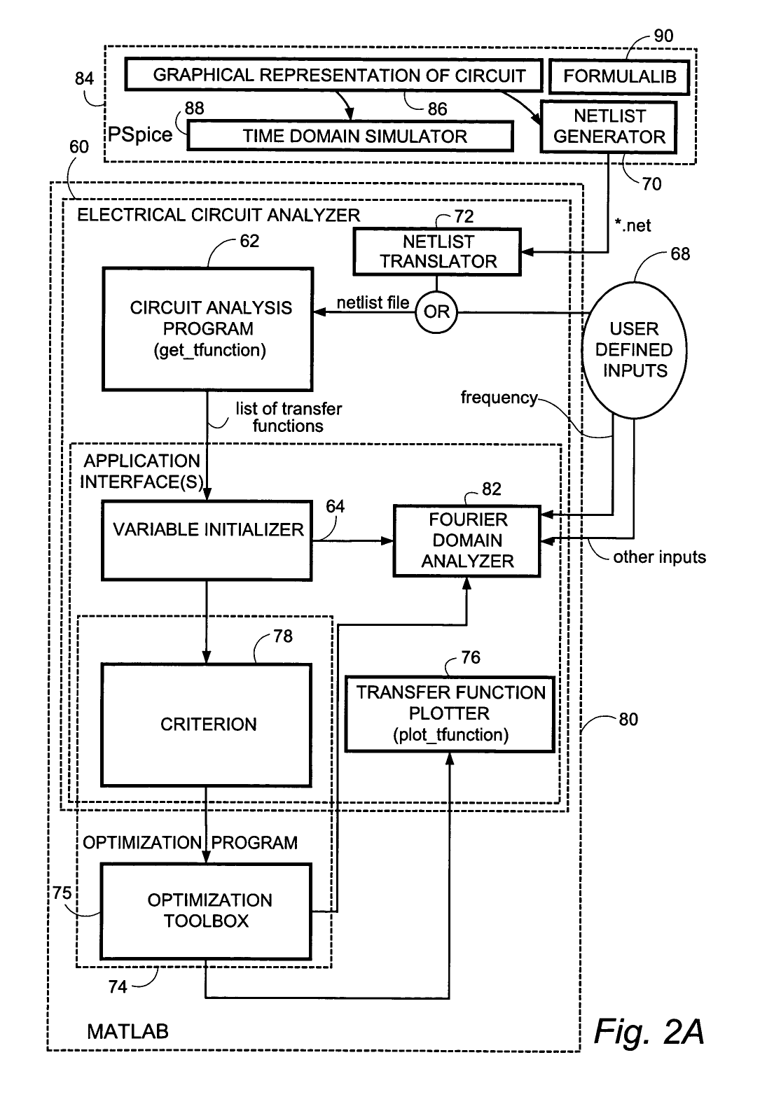

FIG. 2 is a schematic view of an organization of electrical circuit analyzer 60. Electrical circuit analyzer 60 comprises circuit analysis program 62 which is also known as “get_tfunction” (“get transfer function”).

The circuit analysis program 62 receives numerous inputs, including (but not limited to) a netlist file. The netlist file, often referenced as the “netlist” is described in more detail subsequently. The netlist file is a specially formatted listing of components of an electrical circuit which is subject to analysis. The netlist file can be obtained in either of two ways. In a first way, the netlist file is obtained from the user as a user-defined input (user defined inputs being represented by symbol 68 in FIG. 2). In a second way, the netlist file can be obtained from a netlist generator 70. The netlist generator 70 can comprise, for example, a schematic editor which prepares a netlist file “*.net”. To the extent that the *.net file prepared by netlist generator 70 may not be completely compatible with electrical circuit analyzer 60, a formula netlist translator 72 may be utilized to prepare a version of the netlist which is usable by circuit analysis program 62.

The circuit analysis program 62 outputs a list of transfer functions to the program 73 (e.g., applications, analysis, etc.) in conjunction with which circuit analysis program 62 operates. As illustrated in FIG. 2, the program 73 may also receive inputs such as frequency and other inputs.

2.2 Electrical Circuit Analyzer: Example Implementation: Matlab Program Run from a Script File

In one example specific implementation illustrated in FIG. 2A, electrical circuit analyzer 60 is an independent program which is run from a script file. Specifically, in the example illustrated implementation, electrical circuit analyzer 60 is an independent Matlab program. Matlab is an existing mathematics software program represented by broken line 80 in FIG. 2A. The electrical circuit analyzer 60 is shown within broken line 80 because, although not being available with the Matlab program product per se, the electrical circuit analyzer 60 is an independent program which utilizes standard Matlab commands and Matlab's Extended Symbolic Toolbox. For a description of Matlab, see, e.g., The Mathworks Inc., “Matlab, The Language of Technical Computating”, November 2000.

FIG. 2A also illustrates application interfaces, other example programs, and tools/toolboxes in conjunction with which the electrical circuit analyzer 60 can execute, particularly for component optimization operations. Application interfaces for use with electrical circuit analyzer 60 include variable initializer program 64; criterion function 78; transfer function plotter program 76; and Fourier domain analyzer 82. For optimization purposes, the mathematics software program 80 (Matlab) includes an optimization program 74. The optimization program 74 includes optimization toolbox 75 and the criterion function 78. Other toolboxes may include e.g. the signal processing toolbox and a cable tool box.

The variable initializer program 64 is an application interface that sets all initial variables for an optimization which is to be performed by optimization program 74. Variable initializer program 64 requires that circuit analysis program 62 has been run (and of course that the memory has not been cleared after it has been run). The variable initializer program 64 automatically goes through the netlist, searches for all components that are variable, and asks the user to enter component start values, as well as lower and upper bounds. These values are then passed into a file for use in optimization/further analysis.

In the same example, and as further shown by FIG. 2A, a program “PSpice” is utilized as the schematic editor program 84 and netlist generator 70. However “PSpice” is just one example of software that can be utilized with electrical circuit analyzer 60, it being understood that electrical circuit analyzer 60 is not dependent upon any particular schematic editor.

Since the PSpice component library does not include models specific for telecommunication applications, such as models for cables/communication channels, and since the components that the electrical circuit analyzer 60 can handle are limited, the PSpice component library FORMULALIB 90 has been created so the user will know which components are allowed and which are not. The FORMULALIB 90 component library has been adapted only for the electrical circuit analyzer 60

3.0 Script Files

The functions of electrical circuit analyzer 60 can be illustrated in the example of the optimization program 74 and are subsequently described in more detail, as well as their input and output parameters. The programs and functions described herein can be implemented in accordance with any of several different programming techniques. For example, in the illustrated embodiment the electrical circuit analyzer 60 works as a script (not as a function) and, for simplicity, has created in a global fashion, thereby allowing all variables to be shared between the programs.

There are different ways to design a script file for calling electrical circuit analyzer 60, depending on how the electrical circuit analyzer 60 and various applications, e.g. optimization program 74 are going to be used. In general a script file which calls these programs will have a structure including path declarations; a display settings section; an optimization preparation section; and an optimization section. In terms of path declarations, usually a script file starts by loading the paths of all files it might need in Matlab's workspace. When running the electrical circuit analyzer 60 main program, there are different options for display settings. The display settings section holds Boolean flags which indicate what information will be written out to the screen when running circuit analysis program 62. For the optimization to work, a criterion file has to be defined, which (as hereinafter described) is done in the variable func_name.

4.0 Netlists

The “netlist” for a circuit is an ordered sequence of circuit's elements, corresponding node numbers together with symbolic or numeric values. As indicated above, there are two different ways or manners in which netlists can be created. A first way to create the netlist is manual creation by a user in an ASCII file (see symbol 68 in FIG. 2). A second way to create the netlist is by using schematic editor program 84 (see FIG. 2A). These two ways result in slightly different formats for the netlist file imported into electrical circuit analyzer 60, but as hereinafter explained the electrical circuit analyzer 60 generates its own internal netlist which is essentially the same regardless of import source.

In general, a netlist which is utilized by the electrical circuit analyzer 60 is arranged in a predetermined manner, such as the format represented in Table 1. As shown in Table 1, each row of a netlist is formatted with fields. Some of the fields are branch conductivity fields (node1, node2, node3, node4) which specify the nodes to which the terminals of a component are connected. Another field is the “element” or “component” field, which identifies the particular circuit component (e.g., resistor, capacitor). Another field is a “value” or “name” field which specifies the symbolic or numerical value of a circuit component. Optional fields may include various data, for example additional branch conductivity (e.g., more than terminals) or component parameters (e.g., controlled sources). As described more fully herein, netlist can also contain entries which are referred to as subcircuits.

TABLE 1

| node 1 | Node 2 | Element | name | Node 3 | node 4 | A | B |
|---|---|---|---|---|---|---|---|
| 1 | 2 | R | R1 or 100k | 0 | 0 | 0 | 0 |
| 1 | 0 | CAB | ETSI40 | 2 | 0 | 1.5 | U |

Table 1 is a general description of the netlist format which illustrates two example circuit elements. The first example represented by the first non-heading row is for a resistor; the second example represented by the second non-heading row is for an ETSI40 cable type.

In Table 1, the columns bearing headers “node 1”, “node 2”, “node 3”, and “node 4” respectively specify to which nodes the terminals of the element are connected. For two port components, such as resistors, a zero at position node 3 and node 4 is a void value. The “element” column of Table 1 identifies the particular circuit element. The “value” column of Table 1 specifies the symbolic or numerical value of a circuit element. Note that “0” at positions node 3 and node 4 is the same as void in the resistor case, while “0” in the cable case implies that a branch is connected to ground.

In Table 1, the columns “A” and “B” are optional fields which are reserved for cables. Column A holds the length of the cable (in km) while column B holds the value U/D denoting if the signal is transmitted upstreams or downstreams.

More information on how netlists are constructed is provided in subsequent examples, including netlist formats for various component types as described in Section 6.0.

5.0 Admittance Matrix

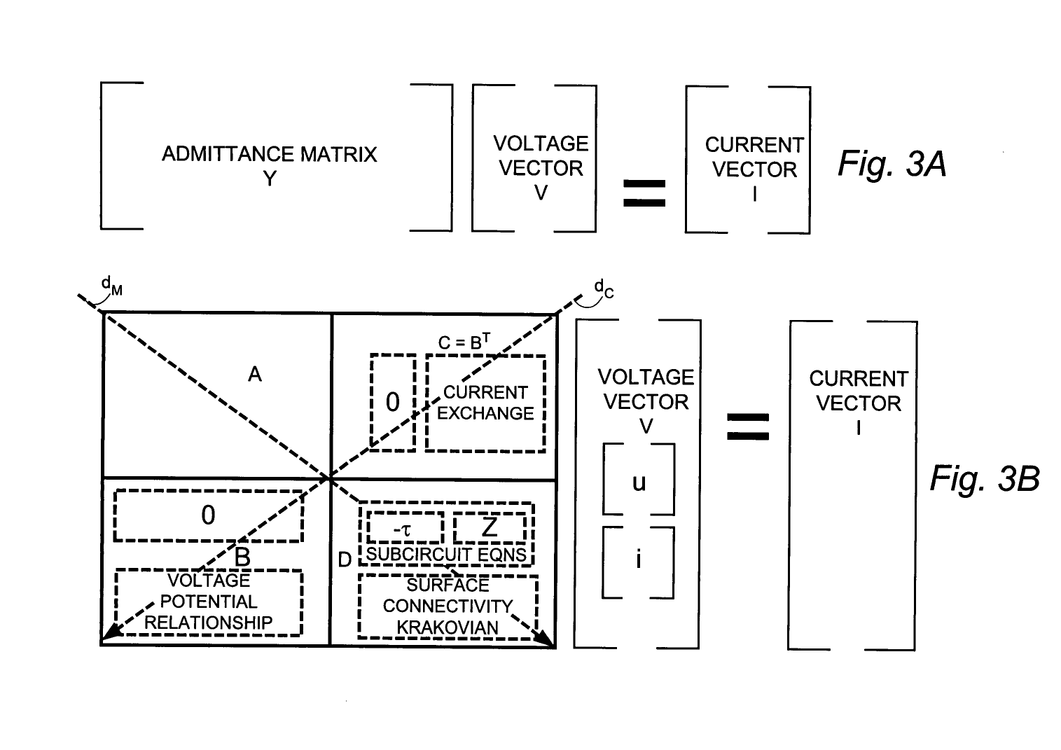

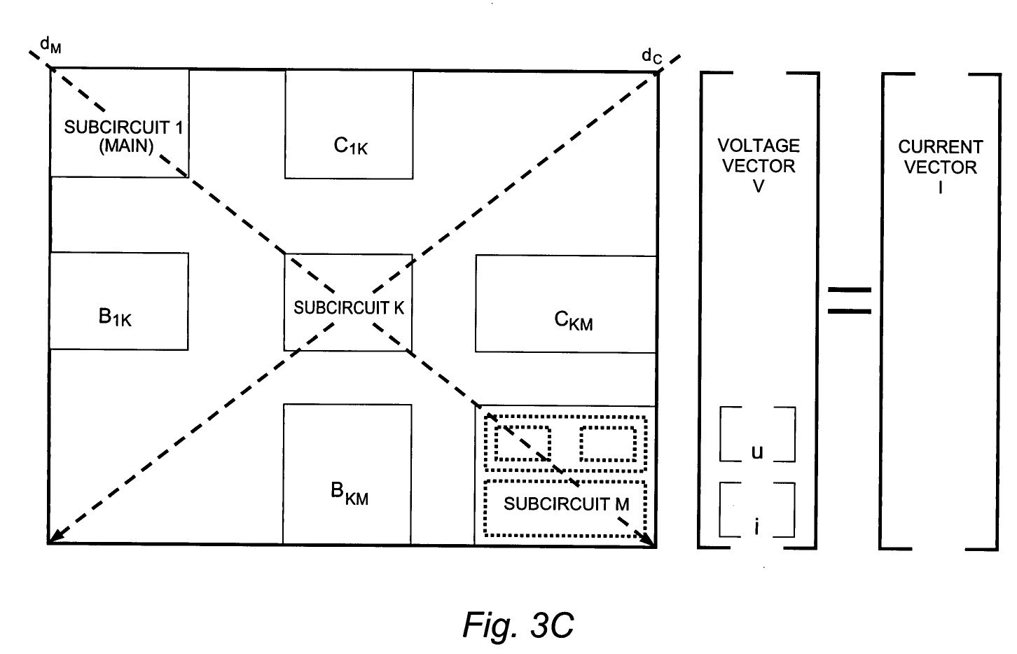

In order for the electrical circuit analyzer 60 to deliver a transfer function, it first has to calculate the potential at every node in the circuit. In the course of doing so, the electrical circuit analyzer 60 generates an equation system YV=I (see FIG. 3A), where I is a current vector, Y is an admittance matrix, and V is the potential (voltage) vector. The electrical circuit analyzer 60 solves for V in the equation system.

In actuality, the admittance matrix Y may not strictly comprise admittance values. That is, although most of the elements of the matrix Y are indeed admittances, the matrix Y may contain entities other than admittances, depending on what components are present in the circuit. The reader will therefore understand that the “admittance matrix Y” as used herein does not have to include only admittances.

Each circuit component, e.g., circuit element, included in an electrical circuit which is analyzed by electrical circuit analyzer 60 affects the admittance matrix Y. Specifically, inclusion of a circuit component involves concomitant inclusions of terms at various positions of the admittance matrix Y, e.g., at various column and row positions. These terms are dictated in accordance with a set of “rules”. That is, the electrical circuit analyzer 60 sets up the admittance matrix Y entries by following a set of “rules”. There is a different rule for each different type of component. The column and row positions of the admittance matrix Y entries affected by the inclusion of the circuit element are typically related to the particular nodes of the circuit to which the circuit component is connected. Some row and columns of the admittance matrix Y entries are not specific to nodes per se, but serve other functions.

Whereas typically in other circuit analysis programs the matrix formulation of electrical circuit equations comprises implicit differential equations, such does not occur for 60. Rather, electrical circuit analyzer 60 sees the electrical circuit as expressed in terms of the frequency domain, Laplace transform domain, or z-transform domain, or as a mixture of these. In general, electrical circuit analyzer 60 reduces the circuit description to a linear and purely algebraic problem which advantageously can be solved straightforwardly. This reduction to a linear and purely algebraic problem results simply from the formation of the problem as a symbolic matrix problem. The admittance matrix comprises symbolic variables or expressions which are thereafter manipulated.

6.0 Component Types

What follows now is a discussion of various types of telecommunications circuit components. For some component types, the netlist format for a user-created ASCII netlist file is shown (PSpice uses another netlist format). In addition, for some components reference is made to an appropriate figure for providing a rule for how each component is placed in the admittance matrix Y. For the netlist format, discussion specifically concerns how the parameters of the components are edited in the FORMULALIB 90 component package of the particular schematic editor PSpice.

Before discussing individual components, is should be noted that when a resistor, inductor, or capacitor is placed in a schematics, schematic editor program 84 (e.g., PSpice) may automatically assign them a name and a value.

6.1 Component Type: Input/Output Terminals

The input and output terminals define the input and output nodes for measuring the transfer function. It is possible to define several transfer functions for one circuit by indexing each input/output pair (just double click on the component in schematic editor program 84, and enter a numeric value). Although these two components will be included in the netlist, they are only markers for electrical circuit analyzer 60, and do not affect the physics of the circuit.

An input terminal is an identifier that specifies the input node. An output terminal is an identifier that specifies output node. It is possible to mark multiple input-output pairs.

The netlist format for an output terminal is as follows:

| | | | | | | | |
|---|---|---|---|---|---|---|---|
| node | 0 | O | index | 0 | 0 | 0 | 0 |

The netlist format for an input terminal is as follows:

| | | | | | | | |
|---|---|---|---|---|---|---|---|
| node | 0 | I | index | 0 | 0 | 0 | 0 |

6.2 Component Type: Resistor, Open End

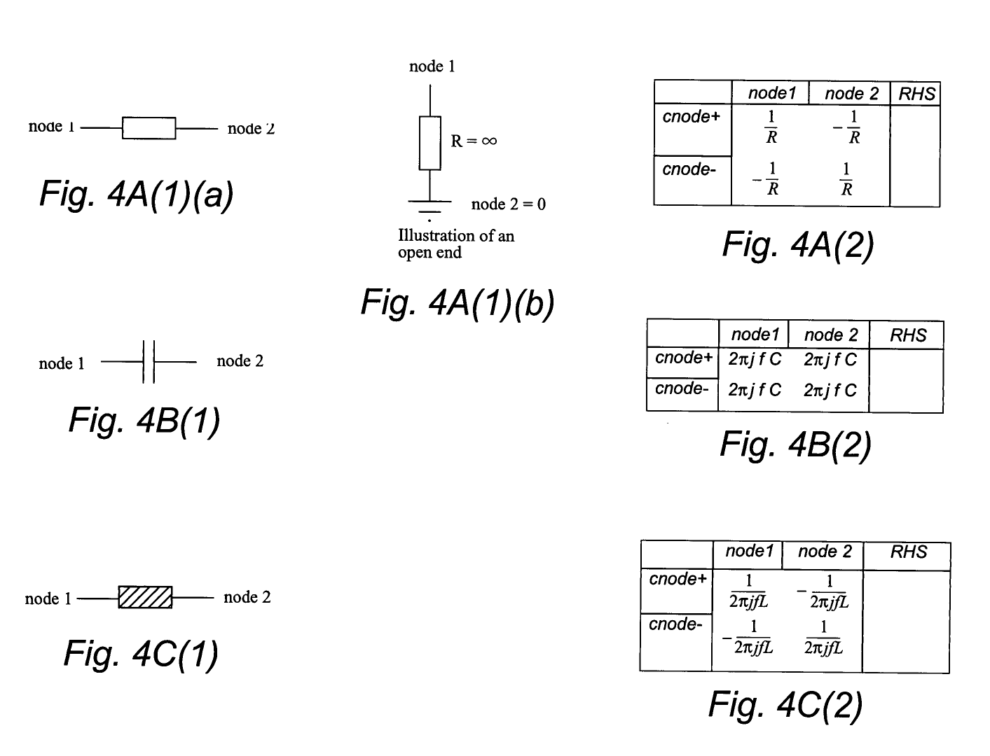

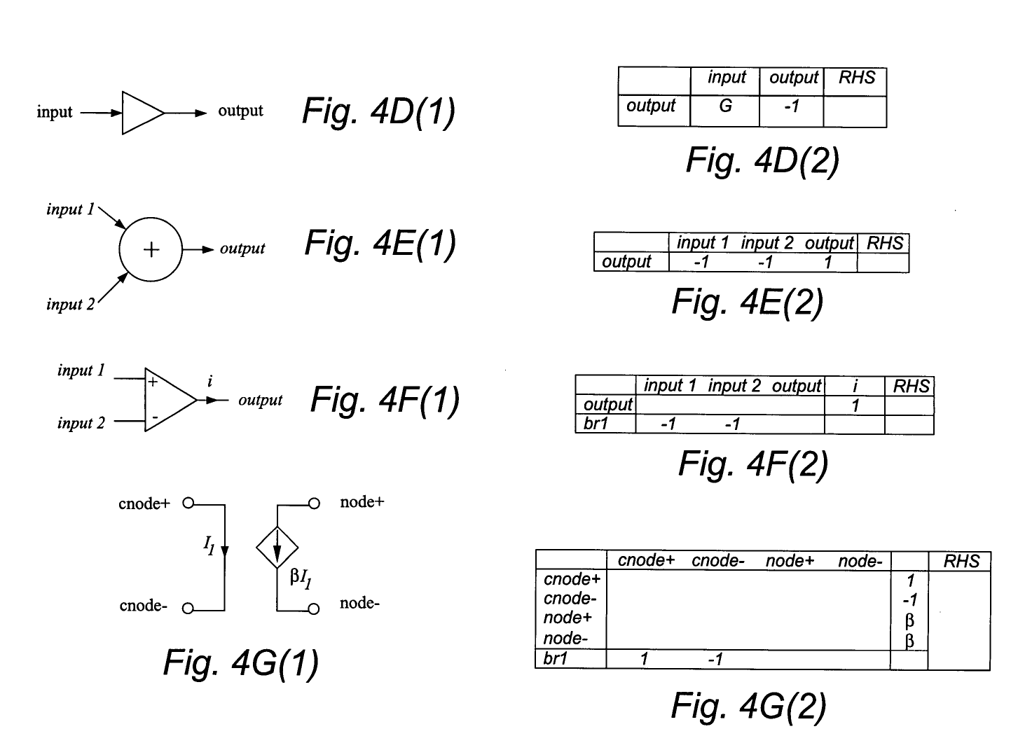

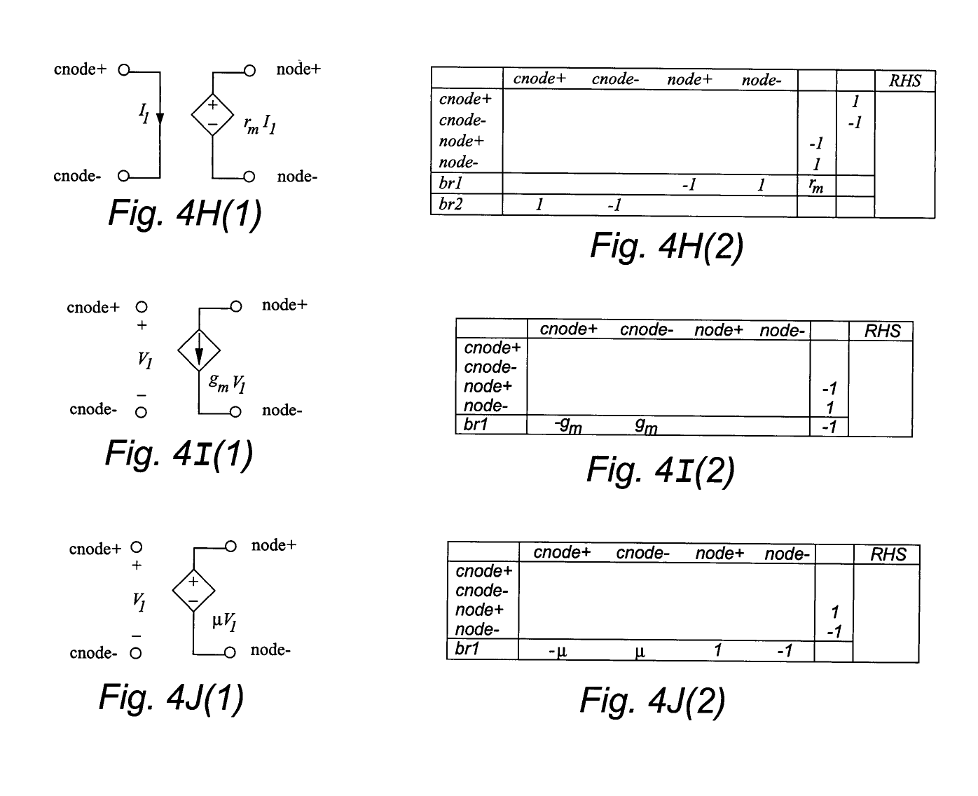

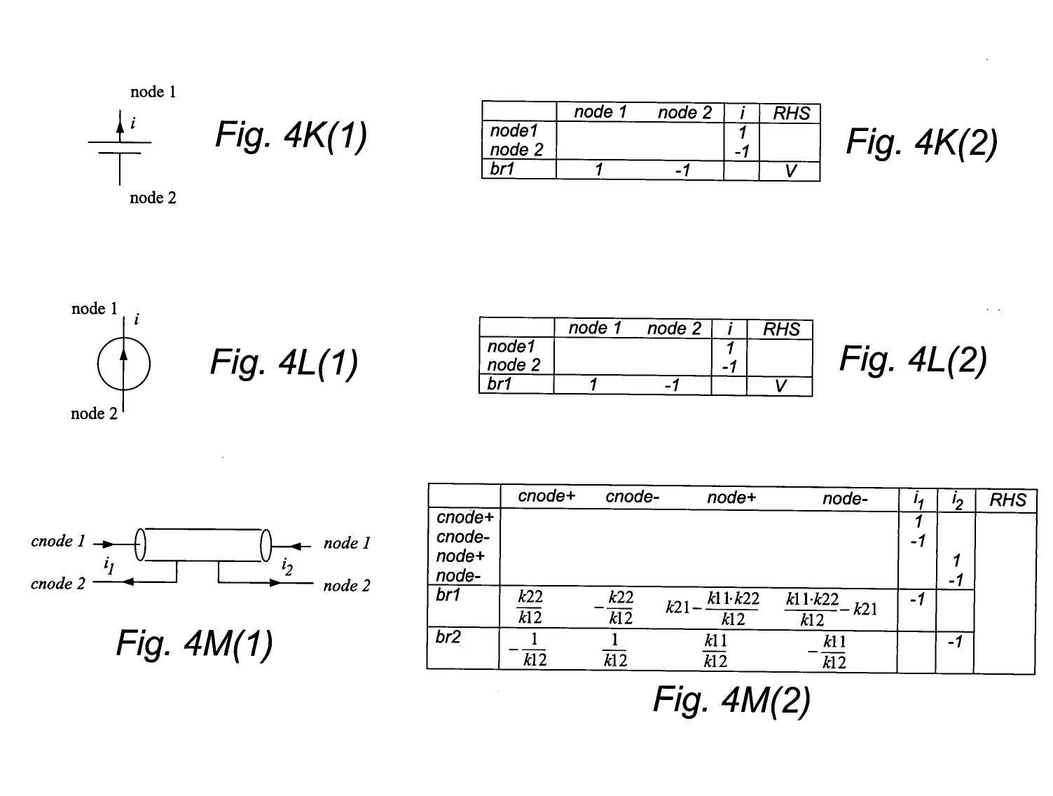

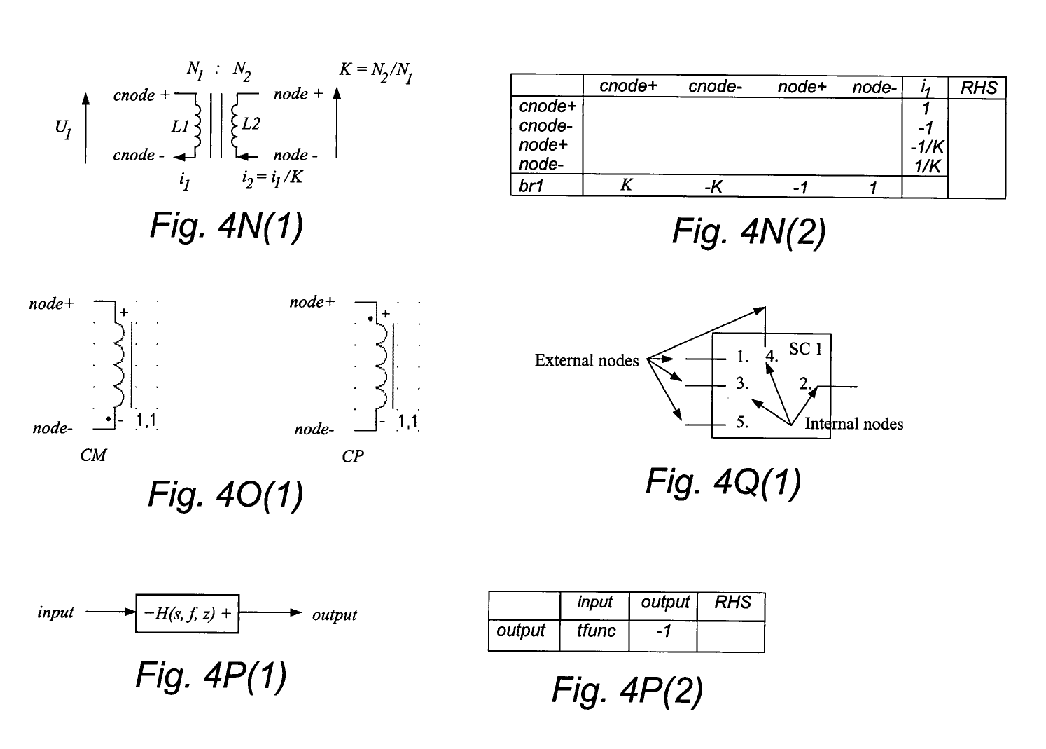

FIG. 4A(1)(a) shows a resistor; FIG. 4A(1)(b) shows an open end. An open-end is a single-input-single-output component with infinite impedance and output terminal connected to ground. An open end is a model of an impedance with zero admittance, connected to ground. FIG. 4A(2) illustrates a rule for placing either a resistor or an open end in admittance matrix Y. The netlist format for a resistor or an open end is as follows:

| | | | | | | | |
|---|---|---|---|---|---|---|---|
| node1 | node2 | R | name/value | 0 | 0 | 0 | 0 |

6.3 Component Type: Capacitor

FIG. 4B(1) shows a capacitor. FIG. 4B(2) illustrates a rule for placing a capacitor in admittance matrix Y. The netlist format for a capacitor is as follows:

| | | | | | | | |
|---|---|---|---|---|---|---|---|
| node1 | node2 | C | name/value | 0 | 0 | 0 | 0 |

6.4 Component Type: Inductor

FIG. 4C(1) shows an inductor. FIG. 4C(2) illustrates a rule for placing an inductor in admittance matrix Y. The netlist format for an inductor is as follows:

| | | | | | | | |
|---|---|---|---|---|---|---|---|
| node1 | node2 | L | name/value | 0 | 0 | 0 | 0 |

6.5 Component Type: Gain

FIG. 4D(1) shows a gain element. A gain element or multiplier is a single-input-single-output component that multiplies its input by a constant, e.g. gain=−1 means setting the output potential to the negative of the input potential. The constant can have numerical (real or complex) or symbolic value. FIG. 4D(2) illustrates a rule for placing a gain element in admittance matrix Y. This stamp overwrites everything that previously might have existed in this row (output) of the admittance matrix. The netlist format for a gain element is as follows:

| | | | | | | | |
|---|---|---|---|---|---|---|---|
| input | output | G | name/value | 0 | 0 | 0 | 0 |

6.6 Component Type: Adder

FIG. 4E(1) shows an adder. An adder is a two-input-single-output component that sums potentials at its inputs. FIG. 4E(2) illustrates a rule for placing an adder in admittance matrix Y. This overwrites over everything that previously might have existed in this row (output) of the admittance matrix. The netlist format for an adder is as follows:

| | | | | | | | |
|---|---|---|---|---|---|---|---|
| input1 | input2 | S | 0 | output | 0 | 0 | 0 |

6.7 Component Type: Operational Amplifier

FIG. 4F(1) shows an operational amplifier. An ideal operational amplifier is a two-input-single-output component with inverting and non-inverting input. It has infinite gain, infinite input resistance and zero output resistance. FIG. 4F(2) illustrates a rule for placing an operational amplifier in admittance matrix Y. In an ideal operational amplifier with infinite gain, Vᵢₙₚᵤₜ₁=Vᵢₙₚᵤₜ₂. There is not much known about the current i leaving the output. This is why no currents for the input 1 and input 2 nodes are included in the matrix stamp. The netlist format for an operational amplifier is as follows:

| | | | | | | | |
|---|---|---|---|---|---|---|---|
| input1 | input2 | E | 0 | output | 0 | 0 | 0 |

6.8 Component Type: CCCSource

FIG. 4G(1) shows a CCCSource (current controlled current source ). Like other controlled sources, the CCCSource is a two-input-two-output component. FIG. 4G(2) illustrates a rule for placing a CCCSource in admittance matrix Y. The netlist format for a CCCSource is as follows:

| | | | | | | | |
|---|---|---|---|---|---|---|---|
| cnode+ | cnode− | CCCS | name/value | node+ | node− | 0 | 0 |

6.9 Component Type: CCVSource

FIG. 4H(1) shows a CCVSource (current controlled voltage source). FIG. 4H(2) illustrates a rule for placing a CCVSource in admittance matrix Y. The netlist format for a CCVSource is as follows:

| | | | | | | | |
|---|---|---|---|---|---|---|---|
| cnode+ | cnode− | CCVS | name/value | node+ | node− | 0 | 0 |

6.10 Component Type: VCCSource

FIG. 4I(1) shows a VCCSource (voltage controlled current source). FIG. 4I(2) illustrates a rule for placing a VCCSource in admittance matrix Y. The netlist format for a VCCSource is as follows:

| | | | | | | | |
|---|---|---|---|---|---|---|---|
| cnode+ | cnode− | VCCS | name/value | node+ | node− | 0 | 0 |

6.11 Component Type: VCVSource

FIG. 4J(1) shows a VCVSource (voltage controlled voltage source). FIG. 4J(2) illustrates a rule for placing a VCVSource in admittance matrix Y. The netlist format for a VCVSource is as follows:

| | | | | | | | |
|---|---|---|---|---|---|---|---|
| cnode+ | cnode− | VCVS | name/value | node+ | node− | 0 | 0 |

6.12 Component Type: Power Supply (DC)

FIG. 4K(1) shows a power supply (DC). FIG. 4K(2) illustrates a rule for placing a power supply (DC) in admittance matrix Y. The power supply is illustrated as a battery. It defines a positive and negative pole. The netlist format for a power supply (DC) is as follows:

| | | | | | | | |
|---|---|---|---|---|---|---|---|
| node1 | node2 | V | name/value | 0 | 0 | 0 | 0 |

6.13 Component Type: Voltage Source

FIG. 4L(1) shows a voltage source. FIG. 4L(2) illustrates a rule for placing a voltage source in admittance matrix Y. The input signal source is currently illustrated as a voltage source. The illustration does not prevent the user from entering a value for the potential difference as a function of the frequency, Laplace or z-transform; V(f,s,z). For instance V=sin 2πf will give an AC-source. The netlist format for a voltage source is as follows:

| | | | | | | | |
|---|---|---|---|---|---|---|---|
| node1 | node2 | V | name/value | 0 | 0 | 0 | 0 |

6.14 Component Type: GCable or a FCable

A cable is a two-input-two-output component represented by a chain matrix. The grounded cable has one input and one output connected to the ground. The numerical values are calculated using elementary cable types, multi section loops or user defined loops. The numerical values of the respective chain matrices are calculated using ITU recommended physical parameters.

There are two different cable models: G(rounded)cable and F(ree)Cable. These cable models are basically the same. The only difference is that Fcable requires that cnode2=node2=0 (ground). Currently electrical circuit analyzer 60 supports both elementary cable types, composed cable loops and allows balanced and unbalanced configuration. The allowed elementary cable types include ETSI32, ETSI40, ETSI50, ETSI63, ETSI90, AWG24, AWG26, DW10, Category5, FP. The allowed composed cable loops include T1.601-Loop1, T1.601-Loop2, T1.601-Loop5, T1.601-Loop7, T1.601-Loop8, T1.601-Loop9, T1.601-Loop13, CSA-Loop4, CSA-Loop6, CSA-Loop7, CSA-Loop8, mid-CSA-Loop, ETSI-Loop1, ETSI-Loop2, ETSI-Loop3, ETSI-Loop4, ETSI-Loop5, ETSI-Loop6, ETSI-Loop7, ETSI-Loop8, VDSL-Loop5, VDSL-Loop6, VDSL-Loop7. All of the above cables may be in the Cable Toolbox except for the ETSI loops and the elementary cables have standardized lengths. Nonetheless, schematic editor program 84 (e.g., PSpice) requires the user to enter a cable length in order to deliver a netlist. However, this value is neglected for those cables with standardized lengths (any value on the length can be entered for those that are not ETSI). The length unit is km.

FIG. 4M(1) shows a cable, which can be a GCable or a FCable . FIG. 4M(2) illustrates a rule for placing a cable (either GCable or a Fcable) in admittance matrix Y. The netlist format for a cable (either GCable or a Fcable) is as follows:

| | | | | | | | |
|---|---|---|---|---|---|---|---|
| cnode1 | cnode2 | CAB | type | node1 | node2 | length | U/D |

6.15 Component Type: Ideal Transformer

An ideal transformer is a two-input-two-output component. The purpose of the ideal transformer is to ‘isolate’ the input and output ports, while satisfying the algebraic equations for voltage-current at its terminals. The ideal transformer is characterized by the number of turns of the primary and secondary coil. That is, an ideal transformer is defined by the numbers N1 and N2 corresponding to number of turns of the primary and secondary coil in figure above. The coils have infinite inductances and coupling coefficient equal to one, i.e. no leakage inductance, and the transformation depends only on turns ratio K=N2/N1. Although an ideal transformer doe not exists in the real world, it can be represented as a practical transformer approximately by an ideal transformer and some additional elements. Otherwise, it can be modeled using CCVSs.

FIG. 4N(1) shows an ideal transformer. FIG. 4N(2) illustrates a rule for placing an ideal transformer in admittance matrix Y. For each transformer coil, it is possible to define the coil number in schematic editor program 84 (e.g., PSpice). The netlist format for an ideal transformer is as follows:

| | | | | | | | |
|---|---|---|---|---|---|---|---|
| cnode+ | cnode− | T | N2/N1 | node+ | node− | 0 | 0 |

6.16 Component Type: Coupled Inductors Aka Transformer

The transformer is a multiple-input-multiple-output component of magnetically coupled inductors. It is characterized by finite inductances of the windings and coupling factors. The coupling between any of the involved inductors is less than one; otherwise the inductance matrix is singular.

FIG. 4O(1) shows coupled inductors. The netlist format for an ideal transformer is as follows:

| | | | | | | |
|---|---|---|---|---|---|---|
| node+ | node− | TC | #transformer | index | CM/CP | [inductances] |

In FIG. 4O(1) and the netlist format, CM and CP are related to the direction in which the windings of the coils are allocated. The “# transformer” denotes to which particular transformer the current winding is connected. “Index” is the number within this transformer attributed to this winding. “The notation “[inductances]” is a string vector, containing information on the respective self inductances as well as coupling factors between the windings of the transformer. There is no rule for a single coupled inductance. However, if several single coupled inductances are detected as being parts of a transformer, these inductances are included as a subcircuit in the admittance matrix.

6.17 Component Type: Transfer Function/File Read Transfer Function

The transfer function is single-input-single-output component that multiplies its input by a given expression. The expression can be symbolic polynomial expression or data imported from a file. Data files are automatically interpolated/extrapolated if necessary. The electrical circuit analyzer 60 handles two different types of transfer functions: the ordinary transfer function (which takes a mathematical formula as parameter) and the transfer function from file (which takes a filename as argument). FIG. 4P(1) shows a transfer function or file read transfer function. The transfer function is modeled in exactly the same way as the gain.

The ordinary transfer function can be entered as a function of the frequency, the Laplace, the z-transform or any other user defined variable. All these variables should in some way be defined as function of the frequency in order for the optimization to work properly.

The transfer function from file reads the transfer function from a file. This option is useful if the user wants to optimize a filter containing a “black box”, whose internal components might be unknown. Then the transfer function across the black box can be measured at certain frequencies, after which these data are placed in a file. The electrical circuit analyzer 60 will then interpolate this data to fit the frequencies that are specified for analysis of the entire filter.

The gain element, the transfer function, and the file Transfer Function are basically essentially similar components. The primary difference is that the gain takes a constant gain factor (either a numerical constant, or a variable), while the transfer function takes a function as argument. The transfer function can be described as a function of frequency (f), Laplace transform (s), z-transform (z) or any other user defined variable. More than one of these variables may also exist in the transfer expression simultaneously; electrical circuit analyzer 60 will automatically substitute, and make the expression a function of frequency.

FIG. 4P(2) illustrates a rule for placing a transfer function (or file read transfer function) in admittance matrix Y.

The netlist format for a ordinary transfer function is as follows:

| | | | | | | | |
|---|---|---|---|---|---|---|---|
| input | output | H | H(s, f, z) | 0 | 0 | 0 | 0 |

The netlist format for a file read transfer function is as follows:

| | | | | | | | |
|---|---|---|---|---|---|---|---|
| input | output | Y | filename | 0 | 0 | 0 | 0 |

6.18 Component Type: Delay

A delay is a single-input-single-output component that delays its input by a constant number of samples.

6.19 Component Type: Subcircuit

A subcircuit is defined as a multiple-input-multiple-output separate electrical circuit, which comprises of a number of the above-mentioned components and/or subcircuits connected together. External nodes couple the subcircuit to the circuit on the higher level (main circuit) whereas internal nodes connect elements and/or subcircuits on the lower level. The subcircuit is represented by block matrix (block Krakovian), which allows its inclusion in the admittance matrix (Krakovian) at the higher level. In the case of several levels the subcircuits are successively involved in the computations

FIG. 4Q(1) shows a representative, example subcircuit. The subcircuit is a dynamic component, i.e. the user must be able from one component called “subcircuit” to define how many nodes the user wants to use. The netlist also has to contain information about how the external branches (those numbered by the GUI) are connected to the internal branches (those numbered by the user) of the subcircuit.

FIG. 3B, previously discussed, illustrates a rule for placing a subcircuit in an admittance matrix. The netlist format for a subcircuit is as follows:

| | | | |
|---|---|---|---|
| circuit | SC | ext.nod1-int.nod1 | ext.nod2-int.nod2 . . . |

The above components are defined as graphical objects in dedicated libraries in schematic editor program 84 (e.g., PSpice), whose main purpose is to assemble a netlist to be imported in the electrical circuit analyzer 60. When one of these components is placed in the schematics, it will automatically be assigned a category, e.g. resistor (R), capacitor (C), etc., and default value, e.g. 1. The value may be reassigned an either numerical or symbolic value.

The electrical circuit analyzer 60 combines symbolic and numerical analysis. It automatically identifies if the variables in the symbolic expressions have some predefined numerical values, evaluates these expressions, and replaces them with numerical values in an early stage. This allows reducing the number of arithmetic operations.

7.0 Main Circuit Analysis Program: Basic Functions

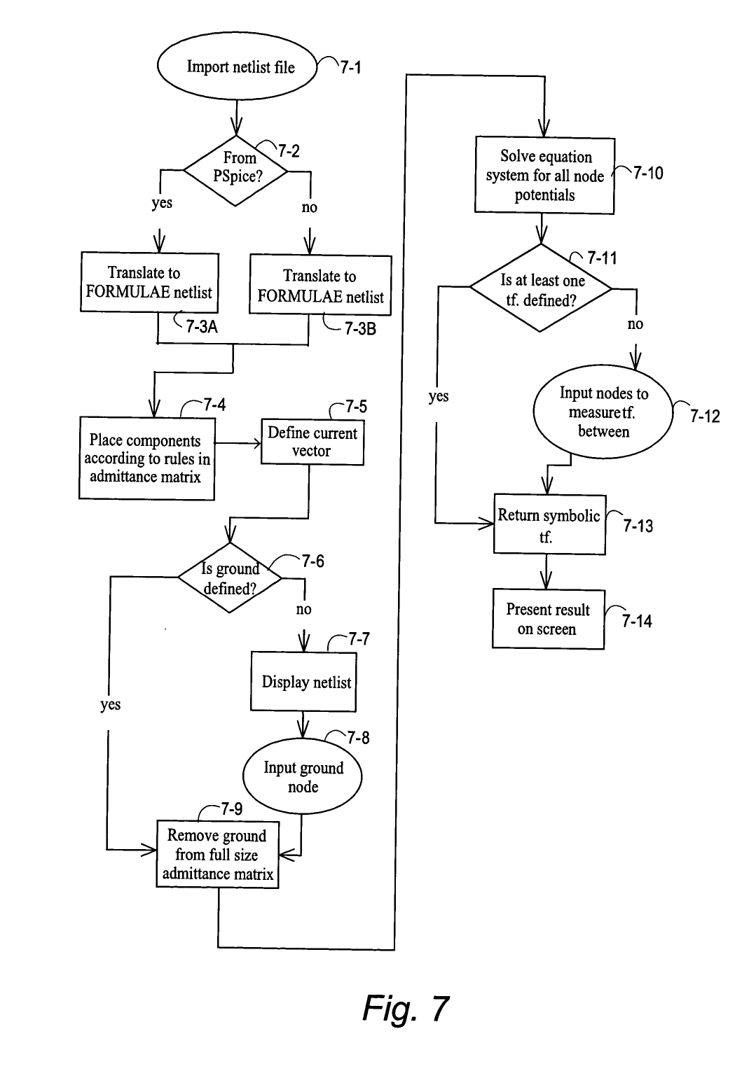

The circuit analysis program 62 performs, e.g., a calculation of the voltage potential at any arbitrary node of the circuit and synthesizes the transfer functions. Basic, representative steps involved in circuit analysis program 62 are illustrated FIG. 7. As previously mentioned, being part of electrical circuit analyzer 60 the circuit analysis program 62 is run from a user created script in which input variables/parameters are defined. The circuit analysis program 62 generates output to the workspace.

7.1 Main Circuit Analysis Program: Input Variable/Parameters

The circuit analysis program 62 receives various inputs, some of which are described above. Unless separately illustrated, these inputs are subsumed in the arrow “other inputs” in FIG. 2 and FIG. 2A. The inputs to circuit analysis program 62 specifically described herein are netlist_file, show_netlist, show_list_of_tfunctions, show_node_potentials, show_admittance_matrix, and f.

The variable netlist_file is of a type string, and contains the name of the netlist. As mentioned above, this netlist can be either created manually (see symbol 68 in FIG. 2) or automatically (e.g., by program PSpice 86 depicted in FIG. 2A). The circuit analysis program 62 automatically detects which kind of netlist is imported. Netlists created from program PSpice 86 all end with the extension .net.

The variable show_netlist is of type Boolean, which means that it takes values 1 or 0. Setting show_netlist=1 will make circuit analysis program 62 show the processed netlist. This function is thought of as a control function at suspicions of errors, to see if circuit analysis program 62 has processed the netlist correctly.

The variable show_list_of_tfunctions is of type Boolean, and determines if circuit analysis program 62 is to display the transfer functions on the display screen 28 or not.

The variable show_node_potentials is of type Boolean, and determines if circuit analysis program 62 is to display a list of all node potentials or not.

The variable show_admittance_matrix is of type Boolean, and determines if circuit analysis program 62 is to display the Admittance matrix on the display screen 28 or not. The admittance matrix contains the node potential equation system, which circuit analysis program 62 will solve before producing the transfer function.

The frequency vector f is of type double, and needs to be initialized if the circuit is going to be optimized, or if the circuit contains cables or transfer functions. If only circuit analysis program 62 is used only for obtaining a netlist that does not contain any of these components, f does not need to be defined.

7.2 Main Circuit Analysis Program: Output Variables/Parameters

The inputs to circuit analysis program 62 specifically described herein are tfunction, tfunction_*, node_potential, ndlist, AdmittanceMatrix, and NewAdmittanceMatrix.

The matrix tfunction is of type sym, and contains all transfer functions. The matrix tfunction has two columns, where at each row the transfer function is written in the first column, and the index of that function as defined in PSpice or manually is written in the second column.

The variable tfunction_* is of type string, and contains the string expression of transfer function with index *. For example, the string expression of transfer function number 5 will be held in variable tfunction_5. The reason for using string expressions is to preserve the dot multiplication in all transfer functions. Evaluation of the transfer function number 5 (in for example a criterion function etc.) is easily done by using the command eval(tfunction_5).

The vector node_potential is of type sym, and contains the node potentials of all nodes in the circuit. To retrieve the symbolic node potential of a node, the user enters (e.g., types) “node_potential(n)”, where n is the node number.

The variable ndlist is a matrix of type sym, and contains the interpreted netlist from circuit analysis program 62. The syntaxes follow the same patterns used when entering manual netlists.

Both AdmittanceMatrix and NewAdmittanceMatrix are matrices of type sym, and represent the admittance matrix (the equation system that circuit analysis program 62 solves in order to find the node potentials). AdmittanceMatrix holds a linearly dependent singular system of rank dim(AdmittanceMatrix)-1. This is because the node for ground has not been defined, and the entire system is “floating”. NewAdmittanceMatrix, however, contains an invertible system after the node for ground has been eliminated. If ground has not been defined in schematic editor program 84 (e.g., PSpice), electrical circuit analyzer 60 will prompt for ground.

8.0 Netlist Generation Example

As indicated previously, the “netlist” is the means by which electrical circuit analyzer 60 receives information on how the components in an electrical circuit are interconnected, and what properties are assigned to each component. One can think of the netlist as a pure (one way) communication channel between the user (GUI or user written netlist) and the electrical circuit analyzer 60. Each row in the netlist, which is presented to the electrical circuit analyzer 60 as an ASCII file when user input is involved, represents one component in the circuit. The netlist does also provide the electrical circuit analyzer 60 with information on which nodes the user has defined as relevant for transfer function analysis.

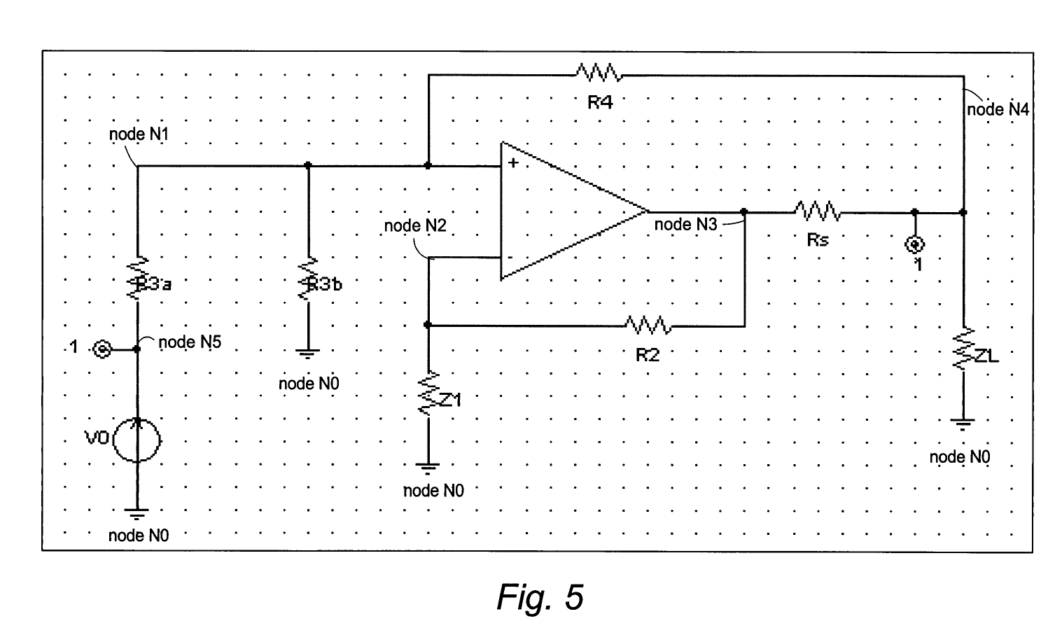

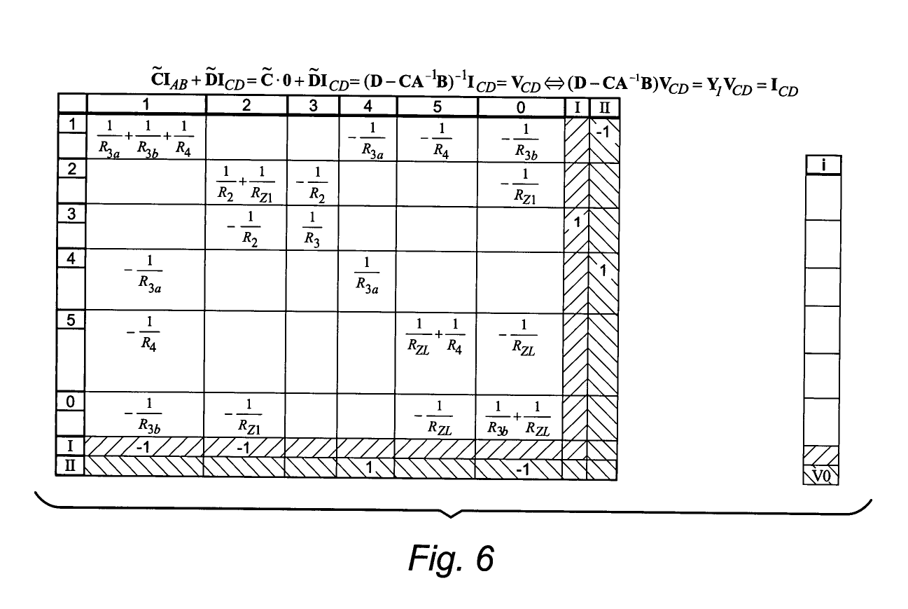

FIG. 5 shows a first example electrical circuit which is to undergo analysis by electrical circuit analyzer 60. The schematics editor 84 (PSpice) creates a netlist file which can be imported into the electrical circuit analyzer 60 for subsequent use (e.g., for computing a transfer function in the manner of Section 10.0 infra).

As previously indicated, the electrical circuit analyzer 60 can read circuit information (such as information about the example electrical circuit of FIG. 5) in two ways, either by importing a netlist from schematic editor program 84 (e.g., PSpice), or by reading a netlist written by the user in an adapted the electrical circuit analyzer 60 netlist language. Although the format slightly varies, these two netlists are equivalent, i.e. none of these contain more information than the other; one can think of them as two different languages, and the electrical circuit analyzer 60 has to interpret either of these to an internal structure. Thus, the netlist itself does not simplify any calculations that the electrical circuit analyzer 60 has to do. The reason for adapting another netlist format than the one received from schematic editor program 84 is to allow the electrical circuit analyzer 60 its own independence.

For the example electrical circuit of FIG. 5, the netlist generated by schematic editor program 84 (e.g., by Pspice) has the form of Table 2, and is referred to as the “Schematics Netlist”.

TABLE 2
Schematics Netlist

| | |
|---|---|
| R_R1 | 0 $N_0001 R3b |
| R_R2 | 0 $N_0002 Z1 |
| R_R3 | $N_0002 $N_0003 R2 |
| R_R4 | $N_0003 $N_0004 Rs |
| R_R5 | $N_0001 $N_0004 R4 |
| R_R6 | $N_0004 0 ZL |
| R_R7 | $N_0005 $N_0001 R3a |
| E_E1 | $N_0001 $N_0002 $N_0003 |
| V_V1 | $N_0005 0 V0 |
| I_P1 | $N_0005 1 |
| O_P2 | $N_0004 1 |

Alternatively, the way an equivalent netlist would be written in a ASCII file by a user for use in the electrical circuit analyzer 60 format is presented in Table 3 below.

TABLE 3
Netlist for Electrical Circuit Analyzer

| | | | | | | | |
|---|---|---|---|---|---|---|---|
| 0 | 1 | R | R3b | 0 | 0 | 0 | 0 |
| 0 | 2 | R | Z1 | 0 | 0 | 0 | 0 |
| 2 | 3 | R | R2 | 0 | 0 | 0 | 0 |
| 3 | 4 | R | Rs | 0 | 0 | 0 | 0 |
| 1 | 4 | R | R4 | 0 | 0 | 0 | 0 |
| 0 | 4 | R | ZL | 0 | 0 | 0 | 0 |
| 5 | 1 | R | R3a | 0 | 0 | 0 | 0 |
| 1 | 2 | E | 0 | 3 | 0 | 0 | 0 |
| 5 | 0 | V | V0 | 0 | 0 | 0 | 0 |
| 5 | 0 | I | 0 | 0 | 0 | 0 | 0 |
| 4 | 0 | O | 0 | 0 | 0 | 0 | 0 |

Whether user-generated or generated by schematics editor 84 (e.g., PSpice), the user-created netlist file as imported into electrical circuit analyzer 60 (and into circuit analysis program 62 in particular) could have the name “test1.net”, for example. The syntaxes defined above are applied to each row (component) in the netlist.

When either the netlist of Table 2 (from schematics editor 84) or the netlist of Table 3 (user-created) is imported to the electrical circuit analyzer 60, the imported netlist will reinterpret them into an internal symbolic matrix structure in the Matlab environment. When running the first example electrical circuit of FIG. 5 through the electrical circuit analyzer 60, the netlist of Table 4 is obtained. That is, Table 4 shows the internal symbolic matrix structure after electrical circuit analyzer 60 has interpreted the netlist from Table 2 or Table 3.

TABLE 4
Internal Post-Interpretation of Netlist
for Electrical Circuit Analyzer

[0, 1, R, R3b, 0, 0, 0, 0]
[0, 2, R, Z1, 0, 0, 0, 0]
[2, 3, R, R2, 0, 0, 0, 0]
[3, 4, R, Rs, 0, 0, 0, 0]
[1, 4, R, R4, 0, 0, 0, 0]
[0, 4, R, ZL, 0, 0, 0, 0]
[5, 1, R, R3a, 0, 0, 0, 0]
[1, 2, E, 0, 3, 0, 0, 0]
[5, 0, V, V0, 0, 0, 0, 0]

9.0 Generation of Admittance Matrix: Example

The electrical circuit analyzer 60 must convert the netlist into a set of (linear) equations in order to algebraically analyze a circuit. As previously described, for most of the components of the electrical circuit being analyzed by circuit analysis program 62 entries are made in admittance matrix Y (see FIG. 3). The nature of the entries and positions (column, row) of the entries depends on the “rule” provided for each type of component. The rules are discussed above for respective components in conjunction with FIG. 4A(2) through FIGS. 4P(2). An example of utilization of these rules in the context of the example electrical circuit of FIG. 5 is below provided.

Each different type of component in the electrical circuit has its own rule table. Consider the resistor R3a in the example electrical circuit of FIG. 5, which is connected between node N1 and node N4, which is the subject of the third line of the netlist of Table 4. The rule for a resistor such as resistor R3a is illustrated in FIG. 4A(2), and for reproduced in Table 5 below.

TABLE 5
Rule for Adding Resistor to Admittance Matrix Y

| | node 1 | node 2 | RHS |
|---|---|---|---|
| cnode+ | 1/R | −1/R | |
| cnode− | −1/R | 1/R | |

For the resistor R3a in the example electrical circuit of FIG. 5, “node1” is Node N1 and “node2” is Node N4. Similarly, “cnode+” is Node N1 and “cnode−” is Node N4. These node references serve as coordinate positions (e.g., row, column positions in the admittance matrix Y. Therefore, in terms of resistor R3a, the rule of Table 5 is as shown in Table 6.

TABLE 6
Rule for Adding Resistor R3a to Admittance Matrix Y

| | node N1 | node N4 | RHS |
|---|---|---|---|
| node N1 | 1/R3a | −1/R3a | |
| Node N4 | −1/R3a | 1/R3a | |

Table 6 indicates that to the matrix position (node N1, node N1) the value 1/(R3a) is to be added; to the matrix position (node N1, node N4) the value −1/(R3a) is to be added; to the matrix position (node N1, node N4) the value −1/(R3a) is to be added; and to the matrix position (node N4, node N1) the value 1/(R3a) is to be added. In other words, from Table 6 it can be seen that 1/R₁ should be sent to position (4,4) and (1,1) in the admittance matrix (additively) and that −1/R₁ should be sent to position (4,1) and (1,4) in the admittance matrix (additively).

For each component in the electrical circuit (e.g., the example electrical circuit of FIG. 5), the electrical circuit analyzer 60 copies (additively) each components' table to the admittance matrix. By copying “additively” is meant that, if two different component tables send matrix elements to the same position in the admittance matrix, these are summed together (i.e. the latter component does not replace what the first component entered in the admittance matrix Y).

The “RHS” column of the tables stands for “Right Hand Side”, and denotes the mapping to the current vector I. In the case of a resistor, the current vector is left unaffected (only the Voltage Source and the Power Supply (DC) add elements to the current vector.) For some circuit components such as the operational amplifier and the voltage source, auxiliary branches are introduced in the admittance matrix (extra rows and columns, which do not correspond to any node in the circuit). The electrical circuit analyzer 60 automatically adds these nodes to the admittance matrix as the electrical circuit analyzer 60 successively process each row of the netlist. The complete matrix for the example electrical circuit of FIG. 5 is shown in FIG. 6.

Using the admittance matrix and the current vector, it is possible for the electrical circuit analyzer 60 to calculate the potentials at any node in the circuit. Introducing auxiliary equations will yield extra variables, but these are disregarded in the analysis. Additionally, the electrical circuit analyzer 60 will automatically remove the row and column in the admittance matrix corresponding to node 0= ground (this is required since the system is over determined otherwise).

10.0 Calculation of Transfer Function: Example

FIG. 7 shows certain example basic steps or actions performed by circuit analysis program 62 of electrical circuit analyzer 60. These basic steps are now discussed in the context of finding a transfer function for an electrical circuit, such as the first example electrical circuit of FIG. 5.

As a prerequisite to analysis of an electrical circuit by electrical circuit analyzer 60, a small script is created. As mentioned above, e.g., in conjunction with Section 2.2, both electrical circuit analyzer 60 and various applications e.g. optimization program 74 are independent programs which are run from a script file created in the Matlab program 80. Creation of the script can involve the user typing “Edit” in the Matlab command window, and then entering the following lines in the editor:

| | |
|---|---|
| netlist_file = ‘test1.net’; | % name of the netlist created by |
| | PSpice |
| show_netlist = 1; | % Boolean value 1 implies show |
| | netlist |
| show_list_of_tfunctions = 1; | |
| show_admittance_matrix = 1; | |
| get_tfunction; | % Runs program to get the transfer |
| | function |
| plot_tfunction = ‘tfunction_1’; | % Plots the first (and only) |
| | transfer function |
| plot_tfunction; | % Plots the transfer function |

The script file should be saved, under the title “test1_script.m”, for example. The script file is executed or run by typing test1_script in the Matlab command window. The line “get_tfunction” of the script file serves to run the circuit analysis program 62.

When the program script file causes running or execution of circuit analysis program 62, the netlist for the electrical circuit is imported as step 7-1. As mentioned several times previously, the electrical circuit analyzer 60 can read or import circuit information (such as information about the example electrical circuit of FIG. 5) in two ways. Accordingly, at step 7-1 the circuit analysis program 62 checks whether the netlist file is imported from a netlist from schematic editor program 84 (e.g., PSpice), or an ASCII file acquired from the user (as indicated by symbol 68). When imported from schematics editor 84, the netlist file may have a name such as “test1.net” and (for the example electrical circuit of FIG. 5) have the content of Table 3. In either case, as step 7-3A and step 7-3B the circuit analysis program 62 uses the formula netlist translator 72 to obtain from the imported netlist file (see Table 3 for an example) a suitable translation of the netlist file usable by the circuit analysis program 62 (see Table 4 for example). As mentioned above, the electrical circuit analyzer 60 has to interpret the netlist file obtained (imported) from either of these two sources to an internal structure for circuit analysis program 62.

As step 7-4, the circuit analysis program 62 places the components of the electrical circuit into the admittance matrix Y. Placement of electrical components into admittance matrix Y is performed in accordance with the placement rules which accompany the discussion of component types set forth in Section 5.0. How the admittance matrix Y is generated for the specific example electrical circuit of FIG. 5 is understood from Section 9.0. The resulting admittance matrix Y for the example electrical circuit of FIG. 5 is shown in FIG. 6.

At step 7-5, circuit analysis program 62 defines a current vector (shown as vector i in FIG. 3A). As step 7-6, circuit analysis program 62 determines if electrical ground for the electrical circuit has been defined in the netlist. If ground has been defined, as step 7-9 the circuit analysis program 62 removes the ground from the full size admittance matrix Y, resulting in the new matrix referred to as “NewAdmittanceMatrix”. In other words, circuit analysis program 62 removes the row and column in the admittance matrix corresponding to node 0= ground (elsewise the system is over determined).

On the other hand, if electrical ground has not been defined, the entire system is “floating”. Accordingly, if electrical ground has not been defined, as step 7-7 the netlist is displayed for the user on display screen 28, so that (as step 7-8) the user is given the opportunity to input a ground node. After the user has defined the ground node, the ground is removed from the full size admittance matrix Y at step 7-9 (resulting in the new matrix NewAdmittanceMatrix).

At step 7-10, the circuit analysis program 62 solves the equation system resulting from the admittance matrix Y for all node potentials. In other words, at step 7-10 the circuit analysis program 62 determines the voltage vector V in the matrix equation system of FIG. 3A.

As step 7-11, circuit analysis program 62 checks whether at least one transfer function has been defined for the electrical circuit undergoing analysis. Circuit analysis program 62 knows whether a transfer function has already been defined by going through the netlist to check whether there already exists at least one input/output pair (since an input/output pair indicates existence of a corresponding transfer function).

If a transfer function for the electrical circuit has already been defined as determined at step 7-11, at step 7-13 the circuit analysis program 62 returns a symbolic expression of the transfer function, which (as step 7-14) is then displayed on a screen of display monitor 28. When the program script comes to the last line, plot_tfunction, it will prompt for some values and invoke the transfer function plotter program 76 to plot the transfer function.

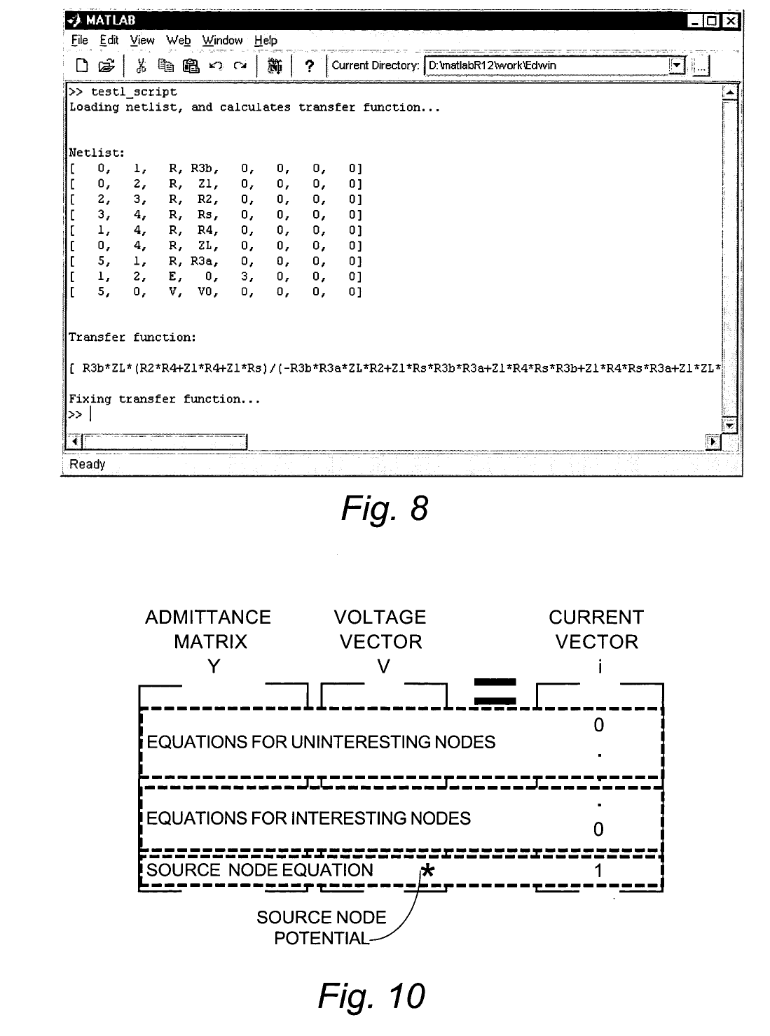

On the other hand, if a transfer function for the electrical circuit has not been defined, then at step 7-12 the circuit analysis program 62 prompts the user to enter (via keyboard 24 or other input means) information indicative of the nodes between which the electrical circuit analyzer 60 is to calculate the transfer function. The transfer function is defined as the output potential divided by the input potential, e.g., the potential at the output node (node N5 of the example electrical circuit of FIG. 5) divided by the potential at the input node (node N1 of the example electrical circuit of FIG. 5). Then, as step 7-13, the circuit analysis program 62 returns the symbolic expression of the transfer function, which is displayed at step 7-14. FIG. 8 shows an example screen display generated at step 7-14 for the example electrical circuit of FIG. 5, and specifically showing the transfer between nodes N1 and N5 thereof.

At step 7-12 the circuit analysis program 62 can prompt the user to enter more than one pair of input nodes for determination of a transfer function. For example, the user may enter a first set of nodes for determination of a first transfer function; a second set of nodes for determination of a second transfer function; and so forth. In such case, the return of the symbolic transfer function at step 7-13 is actually output of a symbolic matrix (“tfunction”) that contains all user-requested (or otherwise prompted) transfer functions.

11.0 Subcircuits: Overview

The matrix equations for electrical circuit analyzer 60 can become increasingly time-consuming and especially memory-consuming when dealing with very large circuits containing many components. Additionally, some components require extensive use of auxiliary equations, which may also contribute to memory deficiencies. In order to minimize these factors, as one of its aspects the electrical circuit analyzer 60 implements a subcircuit matrix approach rooted in Krakovian calculus.

In essence, according to an advantage this block/subcircuit matrix approach, the size of the matrices including the admittance matrix Y is recursively reduced as subcircuits are added to the admittance matrix Y, working only with those matrix blocks that are relevant for a specific application. Thus, the admittance matrix Y dynamically changes its dimensions depending on the number of equations required to describe a subcircuit. Moreover, the solution matrix has approximately the same dimension as the number of relevant equations. For example, if a transfer function is to be calculated between a first node and a second node, the matrix blocks corresponding to the first node and the second node are considered relevant.

Thus, expressing a large circuit in terms subcircuits makes the circuit description easier to interpret. The subcircuit concept can be used many times without creating an excessive amount of equations. The subcircuit concept can also save the number of arithmetical operations.

Modified nodal analysis (MNA) has heretofore limited practical implementation of symbolic computation for large matrices. Since a telecommunication circuit typically contains a large number of components, the matrix calculations are extensively time and memory-consuming and complex. The complexity is due in part to the fact that the equations involved imply or require matrix inversion. It is possible, however, to reformulate the result involving the inverse of a matrix applying the Krakovian algorithm. In general, the electrical circuit analyzer 60 partitions the admittance Krakovian to define the block crucial for a specific application. The block corresponding to subcircuits are successively included in computations.

11.1 Subcircuits: Krakovian Principles

The block/subcircuit matrix approach implemented by electrical circuit analyzer 60 is exemplified by the illustration and derivation described below. The block/subcircuit matrix approach applies principles of Gussian surfaces and conservation law to yield a method of creating an admittance matrix comprising two interconnected subcircuits. There are several advantages of the block/subcircuit matrix approach. As a first advantage, the Krakovian method allows recursively inclusion of consecutive subcircuits into the admittance matrix. Specifically, the admittance matrix can be combined from several individual admittance matrices completed with simple connectivity matrices, one after another. In particular, the admittance matrix can be generated directly from the respective netlists. As a second advantage, the block/subcircuit matrix approach allows splitting admittance matrix into arbitrary smaller block matrices, not necessarily bounded to any physical or electrical structure, in order to perform computations more effectively. The objective may be to separate numerical and symbolic variables or to move certain variables to the top (alternatively to the bottom) of the potential vector, which can be accomplished by an appropriate permutation.

One objective of electrical circuit analyzer 60 is to solve the node potentials in an electric circuit being analyzed. FIG. 3A is a matrix/Krakovian form of the equation system that the node potentials must satisfy, i.e., Expression 1.
YV=I (Expression 1)

In order to determine node potentials of the vector V, the admittance matrix Y must be inverted, i.e., V=Y¹I .

The electrical circuit analyzer 60 permits the circuit undergoing analysis to be conceptualized as plural subcircuits, which streamlines determination of the node potentials as explained below. Or perhaps the user is interested in determining only a few node potentials of a circuit. In either case, it is not necessary to invert the entire admittance matrix Y to solve for the node potential(s). Moreover, all but one of the elements of the current vector I will be zero. One of the elements of the current vector I which corresponds to the “source node equation” has the value of “1”. In other words, the “source node equation” is the equation whose corresponding element in the current vector I has the value of “1”.

The block/subcircuit matrix approach implemented by the electrical circuit analyzer of FIG. 2 exploits these facts together with the Krakovian algorithm, thereby solving the interesting part of the system (the interesting part of the system being either the subcircuit or the portion of the circuit whose node potentials the user wants to determine). This partitioning overcomes the inability of existing mathematics software programs such as Matlab to handle large symbolic equation systems, and results in a much faster approach to matrix equation solution.

As now more generally described, the block/subcircuit matrix approach enables the admittance Krakovian to dynamically change its dimensions depending on the number of equations required to describe a subsequent subcircuit k and having the same dimension as the subcircuit. The dimension of the resulting Krakovian will be bounded above by the size of the main circuit. Furthermore, only the first row of the inverse of the reduced Krakovian is necessary for the solution.

Consider Krakovian Y represented as block Krakovian consisting of Krakovians A, B, C and D. It is assumed that the Krakovians are consistently dimensioned and that the required inverse A⁻¹ exists. Then Expression 2 holds true:

$$Y = ( \begin{matrix}A & C \\ B & D\end{matrix} ) = ( \begin{matrix}τ & {CA}^{- 1} \\ 0 & τ\end{matrix} ) ( \begin{matrix}τ A & τ B \\ 0 & τ {D}_{1}\end{matrix} ) \qquad ( Expression 2 )$$

where
D₁=D−CA⁻¹τB.

The inverses of triangular Krakovians in Expression 2 can be simply obtained as shown in Expression 3.

$$( \begin{matrix}τ & {CA}^{- 1} \\ 0 & τ\end{matrix} ) = ( \begin{matrix}τ & 0 \\ - {A}^{- 1} C & τ\end{matrix} ) and {( \begin{matrix}τ A & τ B \\ 0 & τ D\end{matrix} )}^{- 1} = ( \begin{matrix}τ {A}^{- 1} & 0 \\ - τ {A}^{- 1} τ {BD}_{1}^{- 1} & - τ {D}_{1}^{- 1}\end{matrix} ) \qquad ( Expression 3 )$$

Noting that inverse of Krakovian product equals product of the inverses results in Expression 4.

$${Y}^{- 1} = {( \begin{matrix}A & C \\ B & D\end{matrix} )}^{- 1} = ( \begin{matrix}{A}^{- 1} + ( {A}^{- 1} C ) τ {D}_{1}^{- 1} ( τ {A}^{- 1} τ B ) & - {D}_{1}^{- 1} ( τ {A}^{- 1} τ B ) \\ - ( {A}^{- 1} C ) τ {D}_{1}^{- 1} & {D}_{1}^{- 1}\end{matrix} ) \qquad ( Expression 4 )$$

By appropriately defining subcircuits and sorting Krakovian Y, the equations can be arranged in such a way that the relevant subcircuit equations are represented by the Krakovian A. In this regard, see FIG. 3B wherein the Krakovian A describes a first subcircuit, Krakovian D describes a second subcircuit; and Krakovians B and C represent physically the connectivity between the subcircuit described by A and the subcircuit described by D. Krakovian B=τC. Then the upper-left block Krakovian of Expression 4 will contain all relevant equations for solving the appropriate node potentials.

The first row of the following Krakovian expression is a desirable solution
Ã⁻¹=A⁻¹+(A⁻¹C)τD₁⁻¹(τA⁻¹B) (Expression 5)
assuming that after appropriate permutations the “source node equation” which has the value of “1” was moved to the top of equation system.

Those results lead us to the formulation of recursive algorithm
D_{1,k}=Dₖ−CₖAₖ₋₁⁻¹τBₖ (Expression 6)
Aₖ⁻¹=Aₖ₋₁⁻¹+(Aₖ₋₁⁻¹Cₖ)τD_{1,k}⁻¹(τAₖ₋₁⁻¹τBₖ) (Expression 7)

Observe that the method does not require all equations to be simultaneously available for the computations. The procedure of Expression 7 is repeated for each successive subcircuit until the last calculated Krakovian Aₖ⁻¹ is substituted in Expression 6.

The algorithm derived above plays a central role in symbolic computation in the electrical circuit analyzer 60 because its efficiency, reliability and flexibility.

As mentioned above, vector I is equal to one at only one position and is equal to zero at all other positions. Through suitable permutations of the admittance matrix Y, this element is relocated to be the last element in I, e.g., the first equation in the equation system.

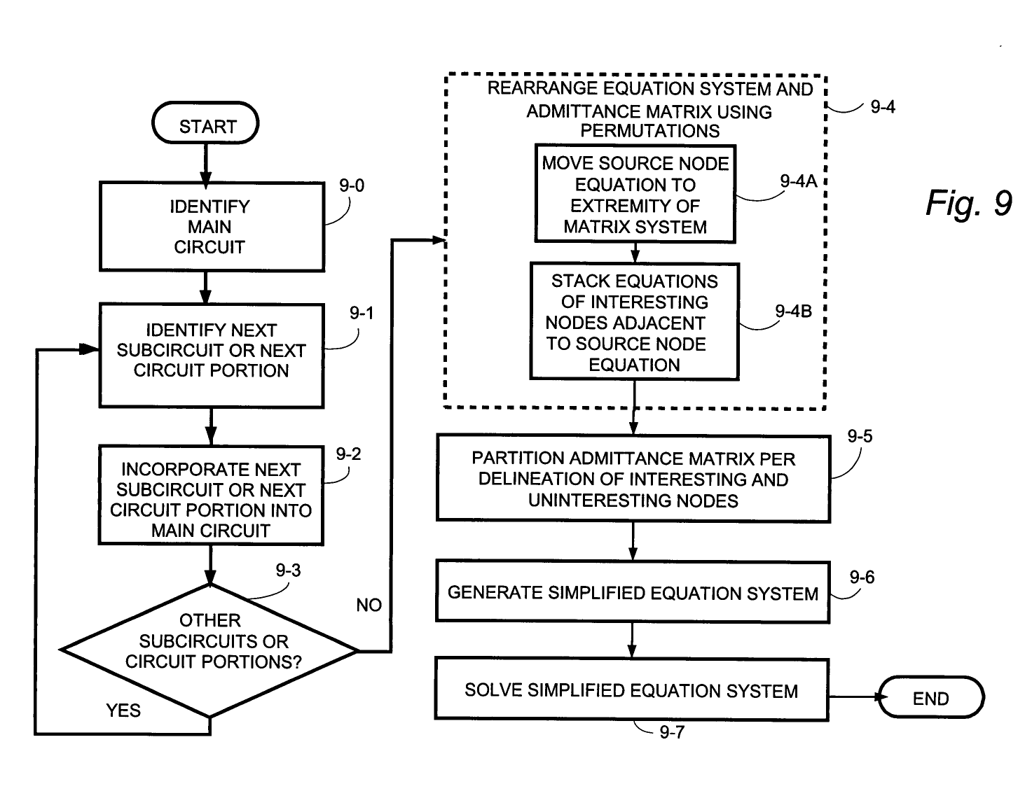

Basic, representative steps involved in the block/subcircuit matrix approach and its technique for inverting partitioning matrices are illustrated in FIG. 9. As step 9-0, the user identifies a first or main circuit or first portion of the overall circuit involved in the analysis, for which the circuit analysis program 62 begins construction of an equation system which includes now includes a matrix for the main circuit as identified at step 9-0. As step 9-1, the user identifies a subcircuit or next circuit portion, which (as step 9-2) is incorporated by circuit analysis program 62 into the equation system which already includes the matrix of the first or main circuit. If it is determined at step 9-3 that there are other subcircuits or other circuit portions which are to be incorporated into the main circuit, steps 9-1, 9-2 and 9-3 are repeated for those other subcircuits or other circuit portions, until the determination at step 9-3 is negative. In the process of performing steps 9-0 through 9-3, the source node equation is the first equation of the equation system, so that effectively the source node equation is moved to the top of the equation system.

Thus, the initial equation system is greatly simplified. Inverses are taken of small matrices (A above) whose sizes, can be set arbitrarily. This is a great advantage of the block/subcircuit matrix approach.

As step 9-4, the admittance matrix Y (and the entire equation system) is rearranged through one or more permutations. These permutations do not substantively affect the equation system as a whole, but only change the order in which the equations occur in the system. One example of the rearranging of the admittance matrix Y in the manner of step 9-4 is illustrated in FIG. 10. Step 9-4 involves the substep 9-4A of moving the “source node equation” to the lowest position in the equation system. The “source node equation” is the equation whose corresponding element in the current vector I has the value of “1”. In contrary to the above described subsequent insertion of consecutive subcircuits into main circuit when the equation system was rearranged so that the source node equation is moved to the top of the matrix system.

As substep 9-4B, all “interesting nodes” and their corresponding equations are stacked above the “source node equation”, as shown in FIG. 10. Substep 9-4B results in all the interesting parts of the circuit being located in the lower part of the equation system, and all “uninteresting nodes” being located in the upper part of the equation system (see again FIG. 10). By “interesting nodes” is meant the nodes whose potentials are relevant to the present analysis.

As step 9-5, the admittance Krakovian Y is partitioned. The partitioning occurs along lines of demarcation of the “interesting nodes” and the “uninteresting nodes”. The “source node equation” is included in the same matrices as the “interesting nodes”. For the illustrated example of FIG. 10, suppose that the admittance Krakovian Y is an N×N matrix, and that the admittance Krakovian Y is partitioned in accordance with Expression 7 into four matrices A, B, C, and D (also known as block Krakovians).

$$Y = [ \begin{matrix}A & C \\ B & D\end{matrix} ] \qquad ( Expression 7 )$$

In the partitioning of Expression 7, A and D are square Krakovians of size p×p and s×s (p+s=N) respectively. So, in accordance with step 9-5, square Krakovians B and D include the equations for the interesting nodes and the source node equation.

By inverting Krakovian A, as step 9-6 a simplified equation system is generated. The simplified equation system disregards the portions of the equation system which included the equations for the uninteresting nodes. So in the Example of FIG. 10 and Expression 7, only the lower partitions of the admittance Krakovian Y, e.g., submatrices B and D, are involved in the simplified equation system. The generation of the simplified equation system is explained below.

In generating the simplified equation system, the inverse of admittance Krakovian Y, e.g., Krakovian Y¹, is partitioned in the same manner as was admittance Krakovian Y. Expression 8 represents the partitioning of the inverse of admittance Krakovian Y.

$${Y}^{- 1} = [ \begin{matrix}\tilde{A} & \tilde{C} \\ \tilde{B} & \tilde{D}\end{matrix} ] \qquad ( Expression 8 )$$

The block Krakovians of the Krakovian Y¹, i.e., Ã, \tilde{B}, \tilde{C}, \tilde{D}, have the same dimensions as block Krakovians A, B, C, D respectively. Moreover, block Krakovians Ã, \tilde{B}, \tilde{C}, \tilde{D}, can be found from Expression 9:

$$( \begin{matrix}{V}_{n} \\ {V}_{y}\end{matrix} ) = {Y}^{- 1} * I = [ \begin{matrix}\tilde{A} & \tilde{C} \\ \tilde{B} & \tilde{D}\end{matrix} ] * ( \begin{matrix}{I}_{n} \\ {I}_{y}\end{matrix} ) = ( \begin{matrix}{A}^{- 1} + ( {A}^{- 1} C ) τ {D}_{i}^{- 1} ( τ {A}^{- 1} τ B ) & - {D}_{1}^{- 1} ( τ {A}^{- 1} τ B ) \\ - ( {A}^{- 1} C ) τ {D}_{1}^{- 1} & {D}_{1}^{- 1}\end{matrix} ) * ( \begin{matrix}{I}_{n} \\ {I}_{y}\end{matrix} ) \qquad ( Expression 9 )$$

where Vₙ, V_{y} and current vector I are appropriately partitioned, and respectively
Iₙ=τ(0 . . . 0)
I_{y}=τ(0 . . . 1)
where D₁=D−CA⁻¹τB

Only one Krakovian equation is considered in step 9-6, namely

$$( \begin{matrix}\tilde{C} \\ \tilde{D}\end{matrix} ) * ( \begin{matrix}{I}_{n} \\ {I}_{y}\end{matrix} )$$

since, as above mentioned, the other part contains no relevant equations in view of the permutations carried out in step 9-1. Upon disregarding the product \tilde{C}*Iₙ, which is equal to zero, Expression 10 is obtained.

$$\tilde{C} {I}_{n} + \tilde{D} {I}_{y} = \tilde{C} \cdot 0 + \tilde{D} {I}_{y} = {( D - {CA}^{- 1} τ B )}^{- 1} {I}_{y} = {V}_{y} \\ ⇔ \\ ( D - {CA}^{- 1} τ B ) {V}_{y} = {Y}_{1} {V}_{y} = {I}_{y} \qquad ( Expression 10 )$$

As observed in Expression 10, the contribution of the block Krakovians B disappears due to the zero vector Iₙ. The equation system Y₁V_{y}=I_{y}, which is of exactly the same form as Expression 1, and contains all the information required to solving the relevant part of the equation system. However, it has been reduced with the size of A, to now only comprise s=N−p equations. The elements of Y₁ will naturally be functions of elements of Y. In order to save memory in the program within which electrical circuit analyzer 60 executes (e.g., Matlab), the elements of Y₁ are now renamed to a new set of variables, which are functions of elements of Y. These functions are written to a file, and can be evaluated during the analysis.

Thus, as step 9-6, the simplified equation system of Expression 11 (which forms part of Expression 10) has been generated.
(D−CA⁻¹τB)⁻¹I_{y}=V_{Y} (Expression 11)

As step 9-7, circuit analysis program 62 solves the simplified equation system generated at step 9-6 to obtain the node potentials of the relevant part of the circuit or the subcircuit currently identified for analysis (e.g., identified at step 9-0, for example). This procedure can be repeated a numerous times, which results in a recursive algorithm. The matrix D₁=(D−CA⁻¹τB) will be subsequently partitioned in the same manner until minimum dimension will be achieved, i.e.
Dₖ=Dₖ₋₁−Cₖ₋₁Aₖ₋₁⁻¹τBₖ₋₁ (Expression 12)
11.2 Subcircuits: Basic Program Steps

The block/subcircuit matrix approach thus separates a subcircuit from the reminder of the circuit, in which case the remainder of the circuit can be referred to as an “main circuit” from the perspective of the subcircuit. On the other hand, from the perspective of the overall circuit, both the subcircuit and the main circuit can be considered as “subcircuits” of the overall circuit, e.g., first and second subcircuits. The subcircuit can be treated as a building block, or component, which can be used in many different circuit analyses. Often, for example, magnetically coupled windings are assembled in a system comprising a transformer, thus being a natural subcircuit application.

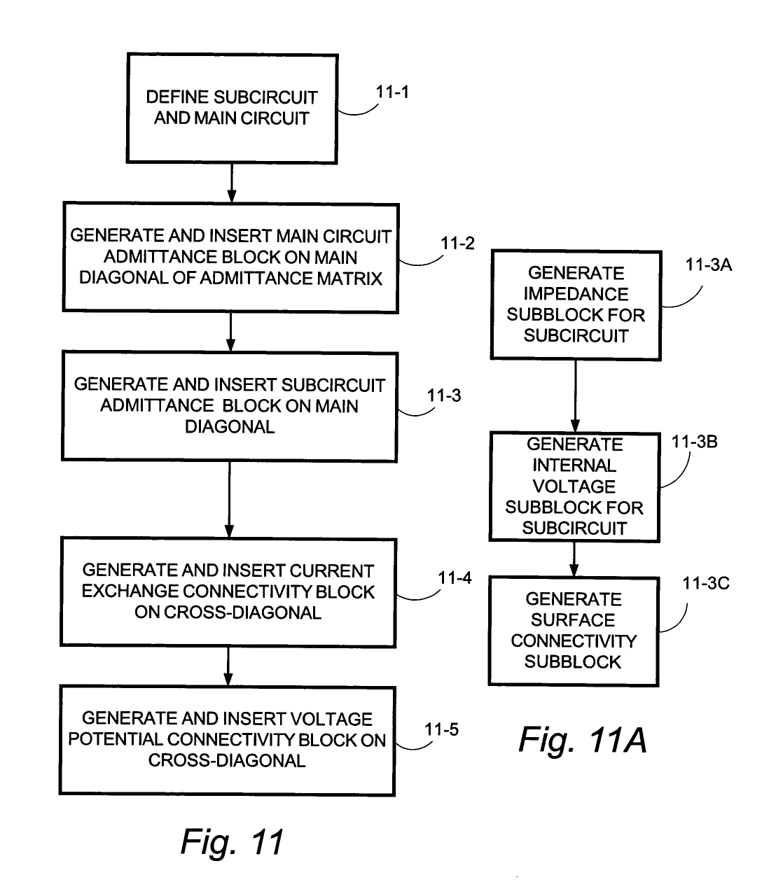

FIG. 11 is a flowchart showing basic steps involved in generation of an Admittance matrix according to the block/subcircuit matrix approach implemented by electrical circuit analyzer 60. The ensuing discussion of the steps of FIG. 11 refer to the equation system of FIG. 3B. As shown in FIG. 3B, the Admittance matrix that will be constructed in accordance with the steps of FIG. 11 actually comprises plural blocks, with some of the blocks comprising subblocks (the subblocks being depicted by broken lines). Specifically, the four blocks that will comprise the Admittance matrix of FIG. 3B are block A, block D, block B, and block C. For sake of reference, the Admittance matrix of FIG. 3B will have a main diagonal depicted by broken line d_{M}, and a cross-diagonal (or off-diagonal) depicted by line d_{C}.

The first step in generation of the Admittance matrix of FIG. 3B is to define the subcircuit relative to the main circuit (step 11-1). As mentioned above, from the perspective of the subcircuit, the remainder of the circuit is the “main circuit”. The step of defining the subcircuit relative to the main circuit includes identifying common nodes which are shared by the subcircuit and the main circuit.

As step 11-2, electrical circuit analyzer 60 generates an admittance block for the main circuit, and inserts the admittance block on a main diagonal d_{M} of the admittance matrix. In the illustration of the Admittance matrix of FIG. 3B, block A is the admittance block for the main circuit. The admittance block A for the main circuit is generated in the manner understood with reference to Section 5.0, in accordance with the components of the main circuit (how the components contribute to the admittance matrix is described in Sections 6.0+).

As step 11-3, electrical circuit analyzer 60 generates an admittance block D for the subcircuit. Further, the admittance block D for the subcircuit is inserted in the Admittance matrix of FIG. 3B on the main diagonal d_{M}, below and to the right of the admittance block A for the main circuit. Generation of the admittance block D for the subcircuit is subsequently described in more detail with reference to FIG. 11A.

As step 11-4, electrical circuit analyzer 60 generates a first of two connectivity blocks, particularly a current exchange connectivity block C. The current exchange connectivity block C is inserted in Admittance matrix of FIG. 3B symmetrically across the main diagonal d_{M}. In this particular embodiment, on the cross diagonal d_{C}, to the right of the admittance block A for the main circuit and above the admittance block D for the subcircuit. Basically, the current exchange connectivity block C describes how currents are exchanged between the main circuit and the subcircuit through the common nodes.

As step 11-5, electrical circuit analyzer 60 generates a second connectivity block, i.e., voltage potential connectivity block B. The voltage potential connectivity block B is inserted on the cross diagonal d_{C} to the left of the admittance block D for the subcircuit and below the admittance block A for the main circuit.

The current exchange connectivity block C and the voltage potential connectivity block B of the Admittance matrix of FIG. 3B essentially form additional equations. Assuming that there are “m” number of common nodes between the main circuit and the subcircuit, the potentials in the m number of common nodes are identical. Moreover, by the conservation law the current leaving a certain node of the main circuit represented by block A is equal to the current entering the same node of the subcircuit represented by block D. These equations are obtained by putting ones (“1”) and minus ones (“−1”) in appropriate places in the current exchange connectivity block C and the voltage potential connectivity block B. Moreover, certain spaces in the current exchange connectivity block C and the voltage potential connectivity block B are equal to zero because potentials can not be equated with currents.

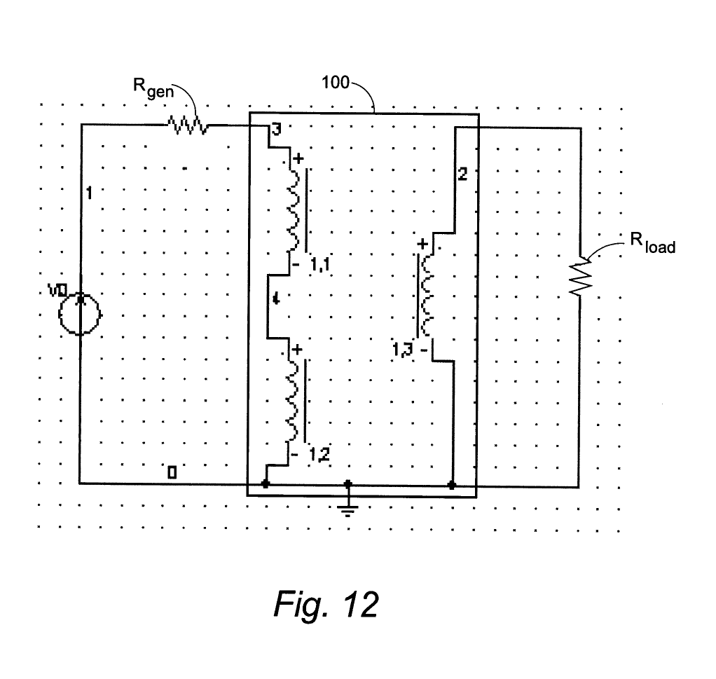

FIG. 11A shows basic substeps involved for electrical circuit analyzer 60 generating the admittance block D for a subcircuit such as that hereinafter described with reference to FIG. 12. The subcircuit 100 can be viewed as a black box with a number of terminals. The subcircuit can be represented by an algebraic equation system, such as admittance equations based on KCL or some other law or abstract relations between currents and potentials. These black box equations are represented by block matrices which are elements of the block D for the subcircuit of FIG. 12(shown in the lower right quadrant of FIG. 3B).

Therefore, as substep 11-3A illustrates, electrical circuit analyzer 60 generates, for inclusion in the admittance block D, a subblock Z for the subcircuit. The subblock Z need not be an admittance matrix, but could as well be a chain matrix or a scattering matrix or any kind of matrix representing a subcircuit. The “surface connectivity Krakovian” may have a complex structure, and depends on how the nodes of the main circuit are connected to the subcircuit and on the formal description of the subcircuits. The square Krakovian to the left of subblock Z is always −τ.

Thus, from the foregoing it can be seen that, in general, block matrices (block Krakovians) corresponding to subcircuits are respective elements on the main diagonal. That is, block D for the subcircuit 100 and block A for the main circuit which is external to subcircuit 100 are on the main diagonal d_{M}. These blocks describe the internal structure of the respective subcircuits. The off-diagonal or cross-diagonal block elements and/or auxiliary blocks represent connectivity between each pair of the subcircuits (e.g., as a Gaussian surface).

The sequence of nodes is irrelevant as long as they are properly assigned within subcircuit and connectivity matrices (Krakovians). This means that the resulting admittance matrix (Krakovian) can be arbitrarily permutated.

The current vector I (see FIG. 3B) in a modified nodal analysis equation system is equal to zero except in positions corresponding to the nodes where the stimulus is applied. Formally then, it is required to calculate only those columns of the inverse admittance matrix.

Moving the interesting elements to the top of current vector corresponds to moving the analogous rows of admittance Krakovian to the top. This naturally constitutes block Krakovian A. Referring to Equation (3) the inverse problem is reduced to recursively inverting smaller matrices. The most obvious advantage occurs during transfer function computation when one of matrices (Krakovian) is a trivial 1×1 matrix.

FIG. 3A illustrates Ohm's Law written in matrix (Krakovian) form. In FIG. 3A, the elements of matrix Y can be not only electrical components such as resistance, capacitance, etc., but also devices having abstract/logical constructions as e.g. VCCS. FIG. 3B shows an equation system including an admittance matrix structured in consideration of a single subcircuit, and thus shows practical execution of the program. At each stage of recursion actual matrix/Krakovian Y is partitioned into four parts, with two subcircuits, one subcircuit in each partition row. FIG. 3C shows that elements of matrix Y can be abstract concepts, i.e. they can be matrices (Krakovians) a.k.a. subcircuits. FIG. 3C illustrates that interconnected subcircuits can be included in the admittance matrix as if they were simple electrical elements. The relations between the circuits are described by entries B and C with coordinates (k,m) and (m,k). In FIG. 3C, the coordinate numbers k and m are not related to single columns and rows, but to a counter of subcircuits.

Thus, the idea of partitioning the admittance Krakovian or matrix can be used for two basic purposes. A first purpose is to include (incorporate) an equation or matrix for subcircuit/subsequent subcircuits into an equation system which already includes the main circuit. In this case, the “source node equation ” should preferably be the first equation in the equation system, and it certainly must be part of the equations or matrix for the main circuit. If it is first equation, then the solution is given as the first row of Krakovian expression 5, if it is the second equation, then by the second row etc. The source node equation must, however, be among the equations describing the main circuit in order to obtain a solution. In so doing, a Krakovian is obtained that represents main circuit with all connected subcircuits. The Krakovian still has the size of main circuit. An advantage is that the circuit analysis program 62 may import all those subcircuits in the netlist form and utilize the information into circuit design at any stage. A second purpose for partitioning applies since, even if the resulting admittance matrix is relatively small, it may be still too big to evaluate numerically within a reasonable time. So essentially the same method is employed to reduce the admittance matrix only to relevant (interesting) equations. In this case “source node equation” should be the last equation., which means that circuit analysis program 62 symbolically inverts smaller krakovians extracted from the upper left corner; defines its elements as new matlab functions, and include the functions as entries of the remaining Krakovian. If the admittance matrix is still too big, the process will be repeated or will be repeated until only interesting equations remain. Consistent with this second purpose, the circuit analysis program 62 obtains a Krakovian which is smaller than a Krakovian representing the main circuit, and the elements of the smaller Krakovian are functions that can be easily evaluated numerically.

Subcircuits: Example

The example electrical circuit of FIG. 12 includes a subcircuit 100. The subcircuit 100 comprises a three winding transformer. The subcircuit 100 of the example electrical circuit of FIG. 12 is connected to the reminder of the circuit of FIG. 12 through four nodes, two nodes being connected to ground. The remainder of the circuit of FIG. 12, i.e., the portions of the circuit of FIG. 12 other than the subcircuit 100, are referred to as the “main” circuit. For subcircuits in general, there can be any number of connections (e.g., any number of nodes) between the subcircuit and the main circuit.

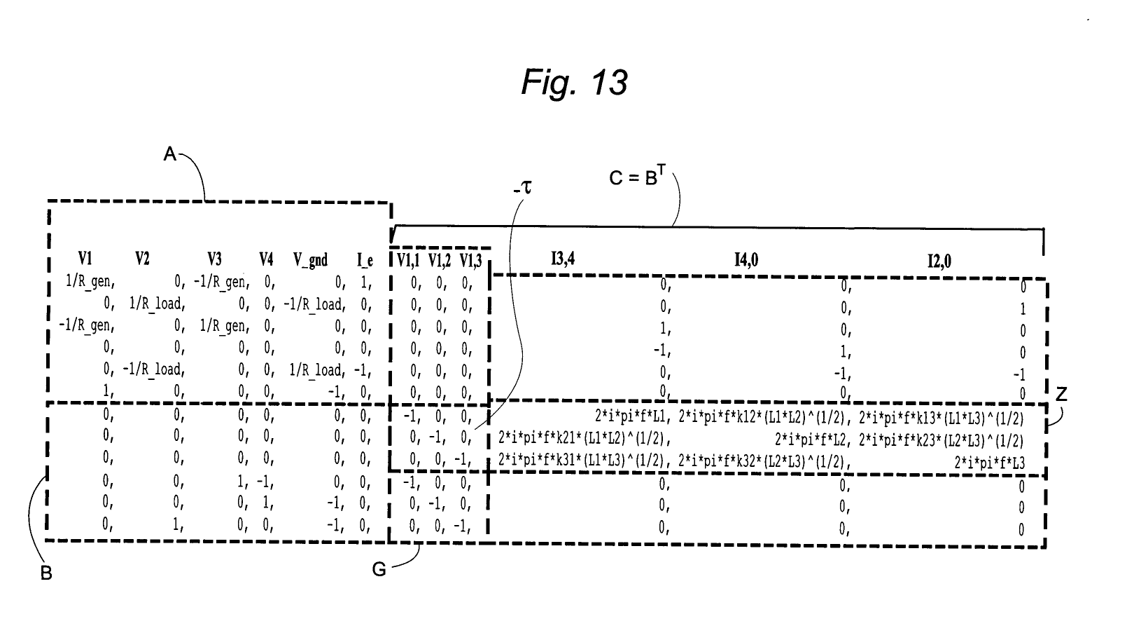

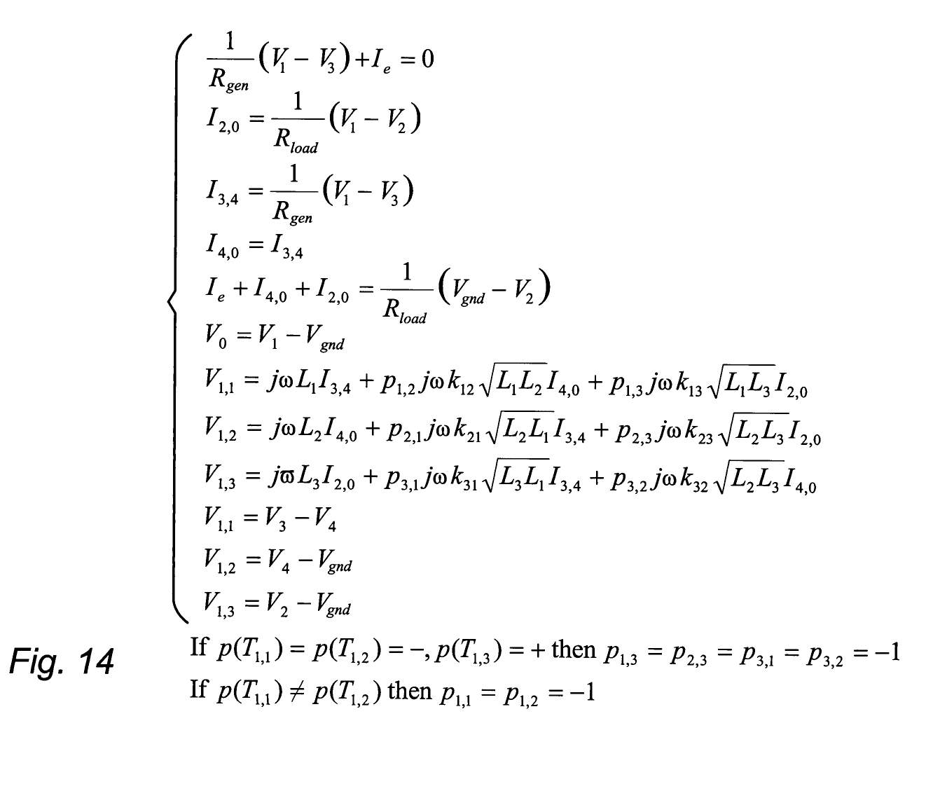

The electrical circuit analyzer 60 creates the admittance matrix of FIG. 13 for the circuit of FIG. 12. The admittance matrix of FIG. 13 has the general format of the admittance matrix of FIG. 3B.

As explained previously, FIG. 3B is a general expression of an equation system including an admittance matrix structured in consideration of a subcircuit (such as the circuit of FIG. 12 having subcircuit 100). The admittance matrix of FIG. 3B has a “main diagonal” depicted by broken line d_{M}. Along the main diagonal d_{M} are an admittance block A for the main circuit and an admittance block for the subcircuit 100. The admittance block A is generated by electrical circuit analyzer 60 at step 11-2 of FIG. 11. The admittance block for the subcircuit is generated at step 11-3 (e.g., steps 12-3A, 12-3B, and 12-3C) and includes subblocks which are essentially in the lower right hand quadrant of the generalized admittance matrix of FIG. 3B. The subblocks comprising the admittance block for the subcircuit include a subcircuit impedance matrix Z; a negative unity Krakovian −τ; and a surface connectivity Krakovian.

The generalized equation system of FIG. 3B further illustrates that, for a circuit having a subcircuit, the potential vector V is extended to include further the vectors u and i. These extensions are necessary in order to mathematically describe the subcircuits. Observe that −τu+ZI=0 describes the relations between the internal currents and potentials in the subcircut. The current exchange Krakovian further is used to add the currents with respective flow from the subcircuit into the main circuit. The voltage exchange Krakovian serves a similar purpose, e.g., to state that the potentials are equal in common nodes.

A main circuit and a subcircuit share one or more nodes, herein called “common” nodes. It is required that the potentials on the common nodes be the same and that currents entering/leaving common nodes also be the same. These requirements are also reflected in the admittance matrix of FIG. 3B. In this regard, the admittance matrix of FIG. 3B has a cross diagonal depicted by broken line d_{C}. The cross diagonal d_{C} extends across the upper right and lower left quadrants of the admittance matrix of FIG. 3B. Block B in the lower left quadrant of the admittance matrix of FIG. 3B is a current exchange block, while block C=B^{T} in the upper right quadrant of the admittance matrix of FIG. 3B is a voltage exchange block. As evident from their notations, the blocks B and C=B^{T} are transposes of one another. Block C=B^{T} has a subblock comprising all zeroes (corresponding to potentials of the subcircuit) and a conductivity subblock matrix which has currents entering/leaving the main circuit nodes. In analogous fashion, the block B has a subblock comprising all zeroes and a conductivity subblock matrix setting equal potentials on the common nodes of the subcircuit and the main circuit.

Inclusion of an electrical component within a simple circuit involves adding an admittance for the component to appropriate coordinates (e.g., matrix positions) in an admittance matrix such as admittance matrix Y of FIG. 3A. The block/subcircuit matrix approach of electrical circuit analyzer 60 involves putting an admittance matrix for the subcircuit on a main diagonal d_{M} of an admittance matrix such as the admittance matrix D of FIG. 3B. In the block/subcircuit matrix approach, subtracting admittances form the respective cross diagonal elements by more complex addition using block matrices instead of elements. The foregoing illustrates a principle or rule for of adding admittances to the main diagonal d_{M}

For the particular example electrical circuit of FIG. 12 having the admittance matrix of FIG. 13, the admittance matrix block of FIG. 13 labeled as “A” corresponds to the main circuit. Admittance block A of admittance matrix of FIG. 13 has been constructed for the main circuit of FIG. 12 in accordance with the admittance matrix construction rules illustrated in Section 6.0.

The subblock labeled as “Z” in FIG. 13 corresponds to the impedances of the subcircuit 100 of FIG. 12. The block labeled as block “−τ” is also a part of subcircuit 100 and relates to the voltages inside the subcircuit 100 with the impedances in the circuit as described in block “Z”. In this specific case (of a transformer), the surface connectivity block only consists of the subblock G=−τ, and zero otherwise, as illustrated in FIG. 13. In a general case, it might not necessarily be so, and the surface connectivity Krakovian can exhibit various patterns.

Block B of the admittance matrix of FIG. 13 is the voltage exchange block. Block C=B^{T} of the admittance matrix of FIG. 13 is the current exchange block. The block C=B^{T} describes how the currents are exchanged between the main circuit and the subcircuit through the nodes that connect them. In a similar way the block B describes the potentials of the external nodes and the potentials in the subcircuit (by means of block G). Both block B and block C=B^{T} are each comprised of a subblock which, for the circuit of FIG. 12, has all zeroes.

The subblock below the subcircuit equations in the admittance matrix of FIG. 13 is known as the surface conductivity Krakovian. For the particular example of FIG. 12, the surface conductivity Krakovian contains −τ and zeroes. In other cases, however, it could turn out that the surface conductivity Krakovian may contain non-zero entries. In a general case, the connectivity Krakovian is not distinctly divided into a −τ block and a zero block, but can be of another pattern reflecting the type of equations described in the subcircuit (impedance matrix, chain matrix, scattering matrix, etc.).

FIG. 14 is a diagrammatic view of an equation system generated by electrical circuit analyzer 60 for the example electrical circuit of FIG. 12 using the admittance matrix of FIG. 13.

The example electrical circuit of FIG. 12 includes a subcircuit 100 which comprises a three winding transformer. It should be understood that the subcircuit approach herein discussed is not limited to any particular subcircuit structure. For example, a subcircuit such as subcircuit 100 could comprise other components, such as telecommunications components such as filters, line-drivers, loading coils, or cables, for example.

From the foregoing it can be seen that, according to the block/subcircuit matrix approach, the concept of a simple two-terminal (one-port) element can be generalized to an elementary subcircuit. The simple two-terminal (one-port) element satisfies the conservation law, i.e. for any voltage applied across terminals, the current entering one terminal equals the current leaving second terminal. A resistor, a capacitor and an inductance are example of such simple two-terminal (one-port) elements. A general one-port element contains an arbitrary number of interconnected devices also satisfying the conservation law. As a rule, a diagonal element k,k in an admittance matrix is the sum of branch admittances attached to node k, while off-diagonal elements k,j and j,k of the admittance matrix are the sum of admittances of all the branches joining nodes j and k multiplied by −1.

Likewise, there can be defined analogous rules for elements having multiple terminals and satisfying particular properties. An operational amplifier is such element.

For example, two-ports networks have two pairs of terminals, each of pair behaving as one port, i.e. the current entering one terminal equals the current leaving the second terminal. The relationships between terminal voltages and currents of the two-ports are usually expressed in matrix form. The internal variables are not considered. Depending on the grouping of currents and voltages variables, there are some commonly used parameters, e.g. impedance parameters, scattering parameters, chain matrices, etc. The controlled sources, ideal transformer and transmission line are also two-ports. Two-ports obey the rules depicted in FIG. 3B.

Multi-ports networks have multiple pairs of terminals, each of pair behaving as one-port and relationships between current and voltage variables are described by set of linear equations. The multi-windings transformers (coupled inductances) are multi-ports. They follow the same rules as two-ports except that number of variables increases.

There are a variety of ways of including subcircuit into admittance matrix depending on its representation, i.e. whether z-parameters (impedance) are used or y-parameters (admittance), h-parameters (hybrid), chain matrices(transmission), etc.

A circuit described by the modified nodal equations can be connected to other circuits by the arbitrary number of nodes. The potentials on each of the common nodes are identical and the sum of the currents leaving/entering each common node is zero. Blocks matrices describing the connectivity between the subcircuits augment the block diagonal admittance matrix. In this case, the surface connectivity Krakovian is represented by concatenation of unity Krakovians τ and −τ.

12.0 Epilogue

Historically, traditional circuit simulators have been built around solvers of ordinary differential equations. The system to be simulated is traditionally typically described by a time-dependent mathematical relationship between the systems inputs, outputs, states, etc. The simulator calculates system behavior over a specified time span. The step size (time interval) is chosen either manually or automatically depending on numerical accuracy of differential equations solved in the process. The result is a numerically approximated time function.

In contrast, the electrical circuit analyzer 60 provides the formal description of analyzed circuit, e.g., admittance matrix, transfer function etc. This formal, symbolic description can be used in various analyses, among others, to generate time signals. Hence the entire calculation (performed on numbers) can be represented as a single algebraic formula. Furthermore, the formula can be manipulated according to certain rules to produce another formula. This new formula may describe/represent another property of the system or may be used to produce time signals without rerunning a simulation.

Reducing a circuit description to linear and purely algebraic problem is an advantage in the sense that it opens new ways to analyze the circuit. This reduction to a linear and purely algebraic problem results from the formulation of problem as a symbolic matrix problem. Hence, the admittance matrix comprises symbolic variables or expressions, which are thereafter manipulated appropriately.

The electrical circuit analyzer 60 uses symbolic matrix formulations of electrical circuits and formal techniques to solve equations resulting in closed-form symbolic expressions. There is no need to use sophisticated techniques for integrating differential equations. The electrical circuit analyzer 60 combines symbolic and numerical analysis. The formal expressions can be evaluated and advanced numeric analysis such as zero-pole analysis, frequency performed using standard software packages, toolboxes, for advanced mathematical, graphical and signal processing routines.

The electrical circuit analyzer 60 is software for symbolic computation using standard Matlab commands and Matlab's Extended Symbolic Toolbox. It performs symbolic analysis under the general assumption that the circuit is linear and time-invariant. The generation of symbolic transfer functions are fully automated and several input-output pairs can be defined simultaneously. The transfer function is determined in terms of circuit elements, frequency, z-variable and constants such as gain, filter coefficients, etc.

By using the symbolic processing of the electrical circuit analyzer 60, a signal is represented as a formula, instead of a stream of numbers. The required function is expressed in terms of symbols until it becomes convenient to compute it numerically (explicitly). Matrix approach to circuit analysis, combined with Matlab's software packages allow analysis of very large and complex circuits, tasks that are otherwise merely impossible for the human hand. The electrical circuit analyzer 60 is an attractive alternative to programming, since the generated formulae represents the entire calculation.

One of the objectives of the electrical circuit analyzer 60 is to support electrical engineers with a tool that allows automatic analysis of an electrical circuit. The electrical circuit analyzer 60 is an attractive alternative to the programming job, as it provides a formula that represent the entire calculation. It makes it possible to analyze very large and complex circuits, which in general is a very demanding and time-consuming task.

The electrical circuit analyzer 60 sets up and solves linear equation systems that fully describe the electrical circuits in frequency domain, as well as automated computation of multiple transfer-functions. Further, it has the capability to study circuits including both time-continuous and digital elements. Moreover, it is a tool that requires no programming from the user, but only simple modifications of the script file. Advantageously, it is integrated with Matlab, which provides access to numerous advanced mathematical routines, and implements a user-friendly graphics interface—PSpice.

The electrical circuit analyzer 60 provides realistic models for components of telecommunications circuits, including (for example) multi-winded transformers, as well as analogue (cables) and digital (filter) elements. It allows symbolic analysis of cables as chain matrices, until it becomes convenient to make numerical computations.

A general concept of Gaussian surfaces or supernodes applied by electrical circuit analyzer 60 allows expression of a large circuit in terms of subcircuits. This makes the circuit description hierarchical and easier to interpret. The subcircuit concept can be utilized many times without creating an excessive amount of equations. The block/subcircuit matrix approach permits recursive update of the required parameters, and also limits the size of inverted Krakovian/matrices to the number of analyzed variables. Hence, the electrical circuit analyzer 60 saves the number of arithmetical operations and is thereby widely usable despite a large number of components in a circuit.

While the invention has been described in connection with what is presently considered to be the most practical and preferred embodiment, it is to be understood that the invention is not to be limited to the disclosed embodiment, but on the contrary, is intended to cover various modifications and equivalent arrangements included within the spirit and scope of the appended claims.

1. A computer program product comprising instructions which are stored in a memory and which, upon execution by a processor, perform steps of:
generating an admittance matrix for an electrical circuit which is being analyzed, the admittance matrix including symbolic expressions rather than numerical expressions for at least some components of the electrical circuit;
linearly and algebraically solving an equation system including the admittance matrix for analyzing at least a part of the electrical circuit.

2. The computer program product of claim 1, further comprising linearly and algebraically solving the equation system including the admittance matrix for one of (1) determining a transfer function between specified nodes of the electrical circuit; (2) optimizing a component of the electrical circuit; (3) perturbation/sensitivity analysis, and (4) general circuit design.

3. The computer program product of claim 1, wherein the electrical circuit has a telecommunications component including one of a multi-winded transformer, a loading coil, a line-driver, an analogue cable, and a filter.

4. The computer program product of claim 1, wherein the admittance matrix comprises admittance blocks for each of plural subcircuits.

5. The computer program product of claim 4, wherein the admittance blocks for the plural subcircuits are situated on a main diagonal of the admittance matrix, and wherein connectivity blocks which represent connectivity between the plural subcircuits are situated symmetrically across the main diagonal of the admittance matrix.

6. The computer program product of claim 1, further comprising
(a) rearranging equations in the equation system in accordance with an identification of interesting nodes for analysis;
(b) partitioning the admittance matrix into partitions accordance with the identification of interesting nodes for analysis;
(c) generating a simplified equation system based on the partitioning of step (b).

7. The computer program product of claim 6, further comprising as step (b) recursively partitioning the admittance matrix into partitions accordance with the identification of interesting nodes for analysis.

8. A computer program product comprising instructions which are stored in a memory and which, upon execution by a processor, perform steps of:
generating an admittance matrix for an electrical circuit which is being analyzed, the admittance matrix including symbolic expressions rather than numerical expressions for at least some components of the electrical circuit;
using symbolic computation to solve an equation system including the admittance matrix for analyzing at least a part of the electrical circuit.

9. The computer program product of claim 8, further comprising using symbolic computation to solve an equation system for one of (1) determining a transfer function between specified nodes of the electrical circuit; (2) optimizing a component of the electrical circuit; (3) perturbation/sensitivity analysis, and (4) general circuit design.

10. The computer program product of claim 9, wherein the electrical circuit has a telecommunications component including one of a multi-winded transformer, a loading coil, a line-driver, an analogue cable, and a filter.

11. The computer program product of claim 9, wherein the admittance matrix comprises admittance blocks for each of plural subcircuits.

12. The computer program product of claim 11, wherein the admittance blocks for the plural subcircuits are situated on a main diagonal of the admittance matrix, and wherein connectivity blocks which represent connectivity between the plural subcircuits are situated symmetrically across the main diagonal of the admittance matrix.

13. The computer program product of claim 8, further comprising
a) rearranging equations in the equation system in accordance with an identification of interesting nodes for analysis;
(b) partitioning the admittance matrix into partitions accordance with the identification of interesting nodes for analysis;
(c) generating a simplified equation system based on the partitioning of step (b).

14. The computer program product of claim 13, further comprising as step (b) recursively partitioning the admittance matrix into partitions accordance with the identification of interesting nodes for analysis.

15. A computer program product comprising instructions which are stored in a memory and which, upon execution by a processor, perform steps of:
generating an admittance matrix for an electrical circuit which is being analyzed by:
generating a main circuit admittance block for a main circuit comprising the electrical circuit which is being analyzed;
generating a subcircuit admittance block for a subcircuit comprising the electrical circuit which is being analyzed;
inserting the main circuit admittance block and the subcircuit admittance block on a main diagonal of the admittance matrix;
generating connectivity blocks which represent connectivity between the main circuit and the subcircuit;
inserting the connectivity blocks symmetrically across the main diagonal of the admittance matrix;
using the admittance matrix for analyzing at least a part of the electrical circuit.

16. The computer program product of claim 15, wherein the step of generating the subcircuit admittance block for the subcircuit comprises:
generating a subblock for the subcircuit;
generating an internal voltage subblock for the subcircuit; and
generating a surface connectivity subblock for the subcircuit.

17. The computer program product of claim 15, wherein the step of generating the subblock for the subcircuit comprises generating one of an impedance subblock, a chain matrix equation, and a scattering matrix.

18. The computer program product of claim 15, wherein the step of generating connectivity blocks comprises:
generating a current exchange connectivity block which describes how currents are exchanged between the main circuit and the subcircuit;
generating a voltage potential connectivity block which describes voltages at common nodes between the main circuit and the subcircuit;
inserting the current exchange connectivity block and the voltage potential connectivity block in the admittance matrix.

19. The computer program product of claim 15, further comprising using the admittance matrix for one of (1) determining a transfer function between specified nodes of the electrical circuit; (2) optimizing a component of the electrical circuit; (3) perturbation/sensitivity analysis, and (4) general circuit design.

20. The computer program product of claim 15, wherein the subcircuit comprises one of a multi-winded transformer, a loading coil, a line-driver, an analogue cable, and a filter.

21. A method of analyzing an electric circuit comprising:
using a computer to generate an admittance matrix for the electrical circuit, the admittance matrix including symbolic expressions rather than numerical expressions for at least some components of the electrical circuit;
using the computer to linearly and algebraically solve an equation system including the admittance matrix for analyzing at least a part of the electrical circuit.

22. The method of claim 21, further comprising linearly and algebraically solving the equation system including the admittance matrix for one of (1) determining a transfer function between specified nodes of the electrical circuit; (2) optimizing a component of the electrical circuit; (3) perturbation/sensitivity analysis, and (4) general circuit design.

23. The method of claim 21, wherein the electrical circuit has a telecommunications component including one of a multi-winded transformer, a loading coil, a line-driver, an analogue cable, and a filter.

24. The method of claim 21, wherein the admittance matrix comprises admittance blocks for each of plural subcircuits.

25. The method claim 21, further comprising situating the admittance blocks for the plural subcircuits on a main diagonal of the admittance matrix, and situating connectivity blocks which represent connectivity between the plural subcircuits symmetrically across the main diagonal of the admittance matrix.

26. The method claim 21, further comprising:
(a) rearranging equations in the equation system in accordance with an identification of interesting nodes for analysis;
(b) partitioning the admittance matrix into partitions accordance with the identification of interesting nodes for analysis;
(c) generating a simplified equation system based on the partitioning of step (b).
(d) solving the simplified equation system.

27. The method claim 26, further comprising as step (b) recursively partitioning the admittance matrix into partitions in accordance with the identification of interesting nodes for analysis.

28. A method of analyzing an electric circuit comprising:
using a computer to generate an admittance matrix for the electrical circuit, the admittance matrix including symbolic expressions rather than numerical expressions for at least some components of the electrical circuit;
using symbolic computation performed by the computer to solve an equation system including the admittance matrix for analyzing at least a part of the electrical circuit.

29. The method of claim 28, further comprising using the symbolic computation to solve the equation system for one of (1) determining a transfer function between specified nodes of the electrical circuit; (2) optimizing a component of the electrical circuit; (3) perturbation/sensitivity analysis, and (4) general circuit design.

30. The method of claim 28, wherein the electrical circuit has a telecommunications component including one of a multi-winded transformer, a loading coil, a line-driver, an analogue cable, and a filter.

31. The method of claim 28, wherein the admittance matrix comprises admittance blocks for each of plural subcircuits.

32. The method of claim 28, comprising situating the admittance blocks for the plural subcircuits on a main diagonal of the admittance matrix, and situating connectivity blocks which represent connectivity between the plural subcircuits symmetrically across the main diagonal of the admittance matrix.

33. The method claim 28, further comprising:
(a) rearranging equations in the equation system in accordance with an identification of interesting nodes for analysis;
(b) partitioning the admittance matrix into partitions accordance with the identification of interesting nodes for analysis;
(c) generating a simplified equation system based on the partitioning of step (b).

34. The method of claim 33, further comprising as step (b) recursively partitioning the admittance matrix into partitions in accordance with the identification of interesting nodes for analysis.

35. A method of analyzing an electric circuit comprising:
using a computer to generate an admittance matrix for the electrical circuit by:
generating a main circuit admittance block for a main circuit comprising the electrical circuit which is being analyzed;
generating a subcircuit admittance block for a subcircuit comprising the electrical circuit which is being analyzed;
inserting the main circuit admittance block and the subcircuit admittance block on a main diagonal of the admittance matrix;
generating connectivity blocks which represent connectivity between the main circuit and the subcircuit;
inserting the connectivity blocks symmetrically across the main diagonal of the admittance matrix;
using the admittance matrix for analyzing at least a part of the electrical circuit.

36. The method of claim 35, wherein generating the subcircuit admittance block for the subcircuit comprises:
generating a subblock for the subcircuit;
generating an internal voltage subblock for the subcircuit; and
generating a surface connectivity subblock for the subcircuit.

37. The method of claim 35, wherein the step of generating the subblock for the subcircuit comprises generating one of an impedance subblock, a chain matrix equation, and a scattering matrix.

38. The method of claim 35, wherein the step of generating connectivity blocks comprises:
generating a current exchange connectivity block which describes how currents are exchanged between the main circuit and the subcircuit;
generating a voltage potential connectivity block which describes voltages at common nodes between the main circuit and the subcircuit;
inserting the current exchange connectivity block and the voltage potential connectivity block in the admittance matrix.

39. The method of claim 35, further comprising using the admittance matrix for one of (1) determining a transfer function between specified nodes of the electrical circuit; (2) optimizing a component of the electrical circuit; (3) perturbation/sensitivity analysis, and (4) general circuit design.

40. The method of claim 35, wherein the subcircuit comprises one of a multi-winded transformer, a loading coil, a line-driver, an analogue cable, and a filter.
